(19) United States
(12) Patent Application Publication
(10) Pub. No.: US 2025/0165679 A1
(43) Pub. Date: May 22, 2025

(54) State Estimation using Physics-Constrained Machine Learning

(71) Applicant: Mitsubishi Electric Research Laboratories, Inc., Cambridge, MA (US)

(72) Inventors: Vedang Deshpande, Cambridge, MA (US); Ankush Chakrabarty, Cambridge, MA (US); Christopher Laughman, Cambridge, MA (US); Abraham Vinod, Cambridge, MA (US)

(73) Assignee: Mitsubishi Electric Research Laboratories, Inc., Cambridge, MA (US)

(21) Appl. No.: 18/512,319

(22) Filed: Nov. 17, 2023

(51) Int. Cl. G06F 30/27

(52) U.S. Cl. CPC G06F 30/27

(57) ABSTRACT

To perform a task based on an internal state of a digital twin simulating an operation of a mechanical system, where at least some state variables of the internal states of the digital twin are subject to constraints derived from the physics of a structure of the mechanical system, a processor executes a neural network including an autoencoder trained to process a current internal state of the digital twin and a current control input to the mechanical system to produce a current output of the mechanical system caused by the current control input and an unconstrained next internal state of the digital twin transitioned from the current internal state based on the current control input, and a neural operator trained to modify the unconstrained next internal state of the digital twin to produce a constrained next internal state of the digital twin satisfying the constraints.

### TECHNICAL FIELD

The present disclosure relates generally to operation of mechanical systems, such as vapor compression systems (VCS) or a robotic manipulator, and more particularly to performing a task based on an internal state of a digital twin simulating control of an operation of a mechanical system.

### BACKGROUND

Various systems, such as a vapor compression system and a robot, are controlled using a state observer. Designing the state observer requires knowledge of dynamics of the system dynamics and a mathematical model that defines the dynamics of the system. In absence of the mathematical model, operational data is collected from the system. Further, the collected operational data is utilized to learn unmodeled dynamics, for instance, using neural networks or Bayesian optimization, and subsequently compute state estimator gains.

Advancements in modeling and numerical computing have led to the emergence of digital twins. The digital twins mirror the behavior of the system. The digital twins can be used for designing the state observer. However, using the digital twin for designing the state observer is challenging. For instance, the digital twin is usually composed of modules that are ‘black-box’, made opaque for reasons such as protection of proprietary information, reduction of code complexity, or improvement of user interfacing and experience. Therefore, the digital twin may not admit a simple model structure with which a classical model-based state observer can be designed. Further, digital twin simulations generate the same outputs as the system using the internal states of the digital twin. However, the internal states are not readily available online from the system.

Accordingly, there is still a need for designing a state observer that can integrate with black-box simulation environments (i.e., digital twin) and use such a state observer for controlling the system.

### SUMMARY

It is an object of some embodiments to provide a system and a method for estimating the internal states of a digital twin simulating control of an operation of a mechanical system. Additionally or alternatively, it is another object of some embodiments to provide such a system and a method that estimates the internal states of the digital twin using a neural network trained to estimate the constrained internal states of the digital twin satisfying constraints derived from the physics of a structure of the mechanical system.

Such an estimation is advantageous for performing a task associated with the mechanical systems. For example, in some embodiments, the mechanical system is a vapor compression system (VCS), and the task includes one or a combination of an estimation of heating/cooling capacities delivered by the VCS to a space, a computation of refrigerant mass in the VCS, control of the VCS, a performance monitoring of the operation of the VCS, anomaly detection in the operation of the VCS, a model predictive control of the VCS.

While it is tempting to train a neural network using loss functions enforcing the internal states of the digital twin to satisfy the constraints, some embodiments are based on recognizing that such training would guarantee the satisfaction of the constraints only with some probability governed by the statistical nature of the machine learning. To that end, it is an object of some embodiments to design a neural network with an autoencoder trained to estimate unconstrained internal states of the digital twin with subsequent enforcement of these constraints that guarantee its satisfaction.

Additionally, while it is tempting to design an analytical module that enforces satisfaction of the constraints, that module may go against the statistical guarantees and computational advantages of the neural networks. Moreover, that module may not be deferential, which in turn may jeopardize the training of the neural network and utilization of the digital twin for performing a subsequent task.

Some embodiments are based on realizing that the module that enforces the constraints on the internal states of the digital twin can be implemented as a neural operator. A neural operator refers to the use of neural networks to approximate or learn an operator in mathematical terms. Some embodiments use a neural operator to learn and approximate mathematical formulations enforcing the satisfaction of the constraints. As a result, a separation of the function of the autoencoder estimating unconstrained internal states of the digital twin and the neural operator enforcing the constraints enables a single neural framework having the advantages of the statistical nature of the neural network allowing to use of this neural framework in subsequent statistical operations such as tracking the internal states of the digital twin with a probabilistic filter, such as a Kalman filter.

In some embodiments, a neural operator can be trained jointly with the autoencoder to ensure the efficiency of the performance of various statistical operations. Notably, the ability of the neural operator to enforce the constraints can be used independently from the autoencoder. However, when the neural operator is jointly trained on the outputs of a decoder of the autoencoder, it is beneficial to keep enforcing the constraints on the outputs of the autoencoder rather than on independently derived unconstrained internal states. This is because the neural operator is partially analytical and partially data-driven. The constraint enforcement part is analytical enabling exact satisfaction of the constraints. However, the map from unconstrained space to the nonnegative orthant that is used in analytical satisfaction of the constraints is a neural layer whose weights are trained using machine learning methods. To that end, in some embodiments, the neural operator is jointly trained with the autoencoder.

As a result, the autoencoder and the neural operator provide a joint framework for estimating the internal states of the digital twin that satisfy the constraints while using the benefits of machine learning and enjoying the guarantees of mathematical formulations. For example, in some implementations, the constraint is a linear inequality in terms of the internal states, and the neural operator encodes the constraint using an equivalent rays-based description of a polytope defined by the linear inequality, such that the unconstrained decoding of the next internal state is passed through a fully connected neural layer which produces a nonnegative vector of a dimension that is compatible with the matrix of rays describing the polytope, and the product of the nonnegative vector with the matrix of rays results in the next internal state satisfying the constraint.

One embodiment executes a probabilistic filter estimating the internal states of the digital twin to produce the sequence of internal states using a prediction model subject to process noise and a measurement model subject to measurement noise, wherein at least one of the prediction model and the measurement model includes the neural network. This embodiment allows iteratively tracking the internal states of the digital twin with probabilistic guarantees provided by a probabilistic filter, such as a Kalman filter.

As a result, some implementations provide a system and a method for estimating the states of the VCS using a physics-constrained machine learning model of the VCS and operational data collected from the VCS. The method uses a surrogate machine learning model and constrained Kalman filter for state estimation. An auto-encoder-based surrogate neural state space model (NSSM) of the VCS is learned from the simulation data collected from a high-fidelity, black-box model of the VCS. The NSSM is designed to explicitly incorporate physics-informed constraints into its architecture ensuring that the predictions obtained from this surrogate model are consistent with the fundamental physics of the system. An extended Kalman filter is designed to use NSSM predictions for estimating the states of the VCS as defined by the original black-box model. The architecture of the constrained NSSM is further leveraged to efficiently incorporate the physics-informed constraints in the estimation algorithms.

Accordingly, one embodiment discloses a method for performing a task based on an internal state of a digital twin simulating control of an operation of a mechanical system, wherein at least some state variables of the internal states of the digital twin are subject to constraints derived from physics of a structure of the mechanical system, wherein the method uses a processor coupled with stored instructions implementing the method, wherein the instructions, when executed by the processor carry out steps of the method, including: executing a neural network including (1) an autoencoder trained to process a current internal state of the digital twin and a current control input to the mechanical system to produce a current output of the mechanical system caused by the current control input and an unconstrained next internal state of the digital twin transitioned from the current internal state based on the current control input, and (2) a neural operator trained to modify the unconstrained next internal state of the digital twin to produce a constrained next internal state of the digital twin satisfying the constraints; and performing the task based on the constrained next internal state of the digital twin.

Another embodiment discloses a device for performing a task based on an internal state of a digital twin simulating control of an operation of a mechanical system including one or more processors configured to: execute a neural network including (1) an autoencoder trained to process a current internal state of the digital twin and a current control input to the mechanical system to produce a current output of the mechanical system caused by the current control input and an unconstrained next internal state of the digital twin transitioned from the current internal state based on the current control input, and (2) a neural operator trained to modify the unconstrained next internal state of the digital twin to produce a constrained next internal state of the digital twin satisfying the constraints; and perform the task based on the constrained next internal state of the digital twin.

### BRIEF DESCRIPTION OF THE DRAWINGS

FIG. 1A illustrates a block diagram of a device for controlling a system, according to some embodiments of the present disclosure.

FIG. 1B illustrates a block diagram for performing a task using a current internal state of a digital twin of the system, according to some embodiments of the present disclosure.

FIG. 1C shows a block diagram of the device including a feedback controller, according to some embodiments of the present disclosure.

FIG. 1D illustrates concurrent control of the system and the digital twin of the system, according to some embodiments of the present disclosure.

FIG. 1E shows a block diagram for online learning of internal states of the digital twin, according to some embodiments of the present disclosure.

FIG. 1F illustrates an implementation of a digital twin simulation module for a building energy system, according to some embodiments of the present disclosure.

FIG. 2 illustrates training of a neural network for learning the internal states of the digital twin of the system, according to some embodiments of the present disclosure.

FIG. 3A illustrates an autoencoder, according to some embodiments of the present disclosure.

FIG. 3B illustrates a schematic of an autoencoder, according to some embodiments of the present disclosure.

FIG. 3C illustrates an example implementation of the autoencoder, according to some embodiments of the present disclosure.

FIG. 4A illustrates an environment for controlling a vapor compression system, according to some embodiments of the present disclosure.

FIG. 4B illustrates a block diagram for controlling the vapor compression system, according to some embodiments of the present disclosure.

FIG. 5 illustrates a method for controlling a robotic manipulator using the device, according to some embodiments of the present disclosure.

FIG. 6 shows a block diagram of a method for performing a task based on an internal state of a digital twin simulating control of an operation of a mechanical system according to some embodiments.

FIG. 7 shows a schematic of a neural operator used by some embodiments.

FIG. 8A shows a schematic of an auto-encoder-based architecture of NSSM according to some embodiments.

FIG. 8B shows a schematic of an auto-encoder-based architecture of NSSM according to some embodiments.

FIG. 9A shows a schematic illustrating the steps executed by the probabilistic filter for estimating the internal states of the digital twin, according to some embodiments of the present disclosure.

FIG. 9B shows a pseudo-code of a method for estimating internal states of mechanical systems, such as VCS, according to some embodiments.

FIG. 10 shows a flowchart 1000 for the training and execution stages of estimating the internal states of a digital twin using the Kalman filter of FIGS. 9A and 9B according to an embodiment configured to perform a task for an operation of VCS.

FIG. 11 is a flowchart of an example process according to some embodiments.

FIG. 12 is a schematic of an example process for training the neural network according to some embodiments.

FIG. 13 shows a schematic diagram of a computing device that can be used for implementing the device of the present disclosure.

The presently disclosed embodiments will be further explained with reference to the attached drawings. The drawings shown are not necessarily to scale, with emphasis instead generally being placed upon illustrating the principles of the presently disclosed embodiments.

### DETAILED DESCRIPTION

In the following description, for purposes of explanation, numerous specific details are set forth in order to provide a thorough understanding of the present disclosure. It will be apparent, however, to one skilled in the art that the present disclosure may be practiced without these specific details. In other instances, apparatuses and methods are shown in block diagram form only in order to avoid obscuring the present disclosure.

As used in this specification and claims, the terms “for example,” “for instance,” and “such as,” and the verbs “comprising,” “having,” “including,” and their other verb forms, when used in conjunction with a listing of one or more components or other items, are each to be construed as open-ended, meaning that that the listing is not to be considered as excluding other, additional components or items. The term “based on” means at least partially based on. Further, it is to be understood that the phraseology and terminology employed herein are for the purpose of the description and should not be regarded as limiting. Any heading utilized within this description is for convenience only and has no legal or limiting effect.

Feedback occurs when outputs of a system are routed back as inputs as part of a chain of cause-and-effect that forms a circuit or loop. The system can then be said to feed back into itself. For example, state feedback control is a control technique used in the field of control systems engineering, which involves using a state (or a measurable and/or estimated subset) of the system to compute control actions and regulate the system's behavior.

In a control system, the “state” refers to a set of variables that describe the system's internal dynamics and behavior at any given time. The set of variables includes position, velocity, acceleration, temperature, pressure, or any other measurable or unmeasurable quantities that characterize the system. The state feedback control utilizes a feedback loop where the system's state is measured or estimated, compared to a desired state, and a difference (known as an error) is used to calculate control signals that are applied to the system. The control signals are designed to steer the system toward the desired state by influencing its dynamics.

However, for many industrial systems and processes, the notion of the state of the system is too abstract and/or complex to be practical. For example, manufacturing processes, monitoring and controlling industrial equipment, and optimizing energy consumption in buildings rely on too many state variables that are impractical to measure in real-time control applications. Examples of such unmeasured state variables are pressures or enthalpies in vapor compression systems. In other applications, the notion of state variables is even ill-defined. For example, it is reasonable to assume that a coupling between independent processes in a complex manufacturing system participates in forming a state of the manufacturing system. However, it is often not even clear how to measure and define such a coupling and/or whether such coupling exists in the first place. Accordingly, for many practical applications, state feedback control is impractical or even impossible.

Some embodiments are based on the recognition that digital twins can be used for controlling the system. A digital twin is a digital representation of an intended or actual real-world physical product, system, or process (physical twin) that serves as an effectively indistinguishable digital counterpart of physical twins for practical purposes, such as simulation, integration, testing, monitoring, and maintenance. The digital twin can be used for optimizing manufacturing processes, monitoring and controlling industrial equipment, analyzing patient health data for personalized medicine, optimizing energy consumption in buildings, and even modeling and simulating entire cities for urban planning.

For a sequence of inputs, the digital twin of the system generates the same sequence of outputs that the system may output for the sequence of inputs. In other words, the dynamics of the digital twin provide a mapping between the sequence of inputs and the sequence of outputs. However, the digital twin has its own dynamics. For instance, internal states of the digital twin are usually different from internal states of its physical twin (i.e., the system). Moreover, in contrast with the physical twin, the internal states of the digital twin may have no physical meaning and depend on objectives of a designer of the digital twin. Further, the digital twin may have a complex internal dynamical model with unknown components, which means that the dynamics of the digital twin is unknown.

To that end, it is an objective of some embodiments to capture or learn the dynamics of the digital twin that provides a mapping between the sequence of inputs and the sequence of outputs. The internal states of the digital twin represent a current dynamical state of the digital twin. A sequence of internal states captures the dynamics of the digital twin and that dynamics is supposed to be the same for the digital twin and the physical twin even if the digital twin has different kinds of states, because the same dynamical system can have infinite state representations. Therefore, using the sequences of inputs and the sequence of outputs, the sequence of internal states of the digital twin including the current state can be recovered.

Some embodiments are based on the realization that a neural network can be trained to estimate the sequence of internal states of the digital twin that maps the sequence of inputs to the sequence of outputs, wherein the sequence of internal states represents the dynamics of the digital twin. Some embodiments are based on further realization that, in order to accurately estimate the sequence of internal states, an initial internal state(s) can be applied to the neural network. To that end, in an embodiment, a state estimator (optimization problem) is used to minimize an error between outputs of the system and outputs of the digital twin and then determine the initial internal state for the neural network.

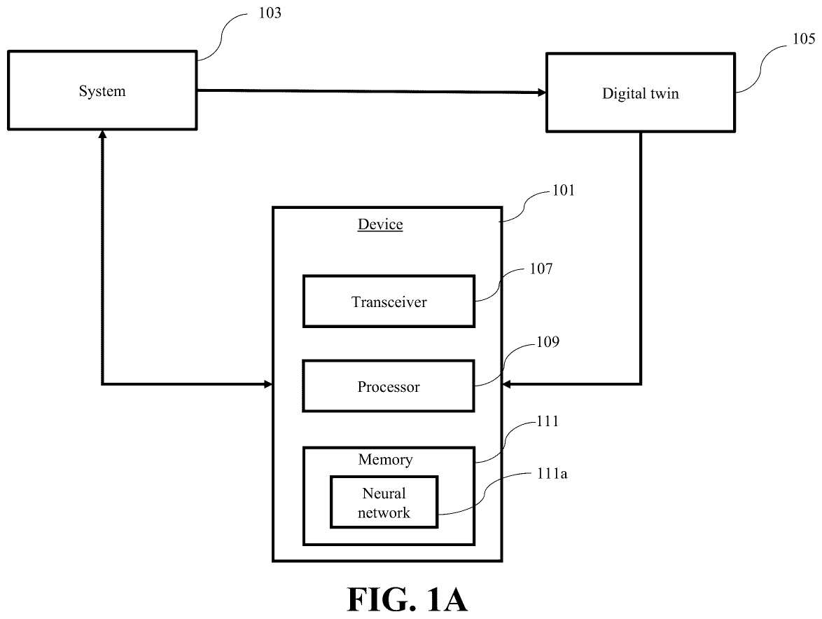

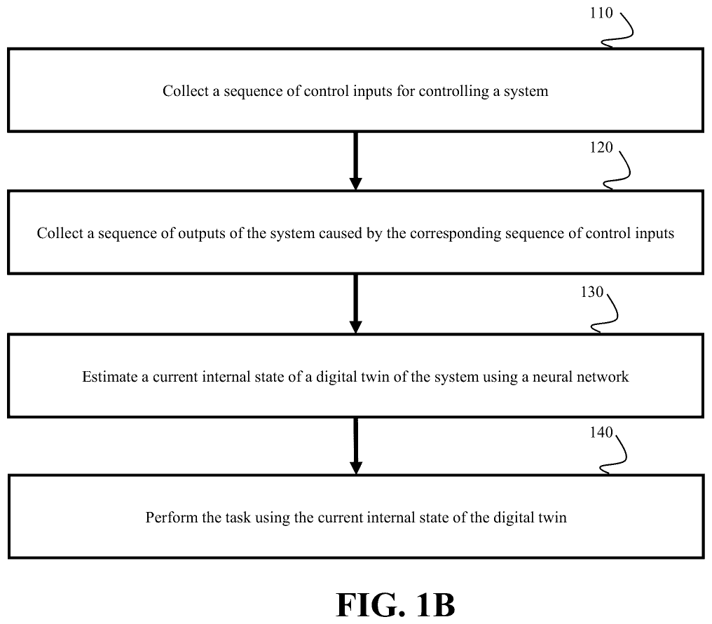

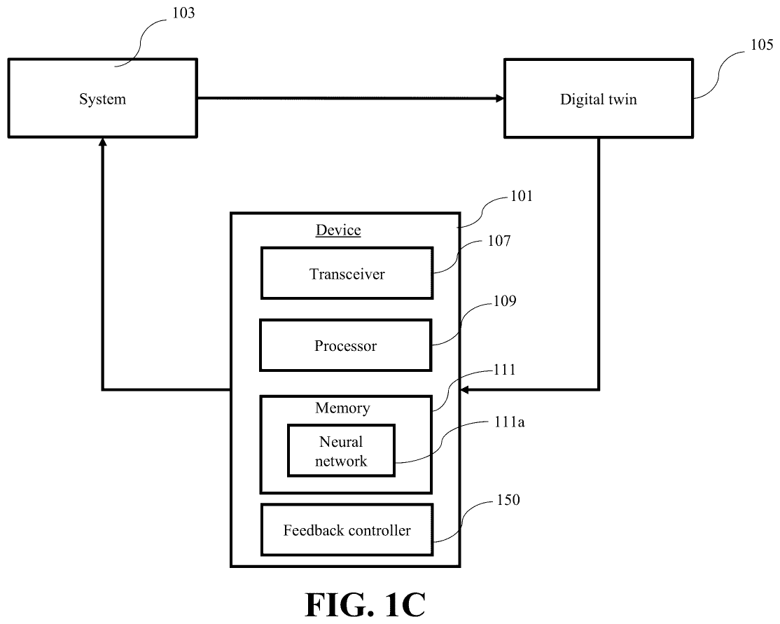

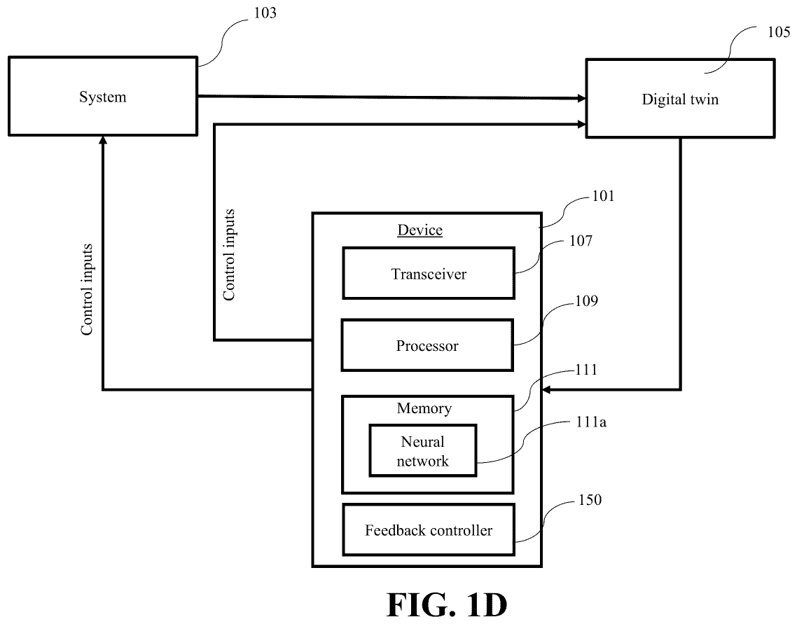

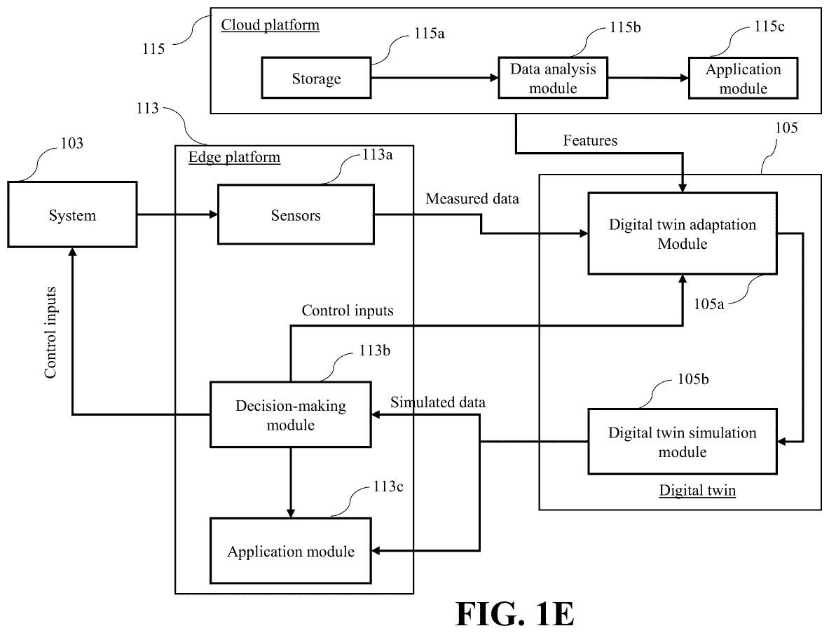

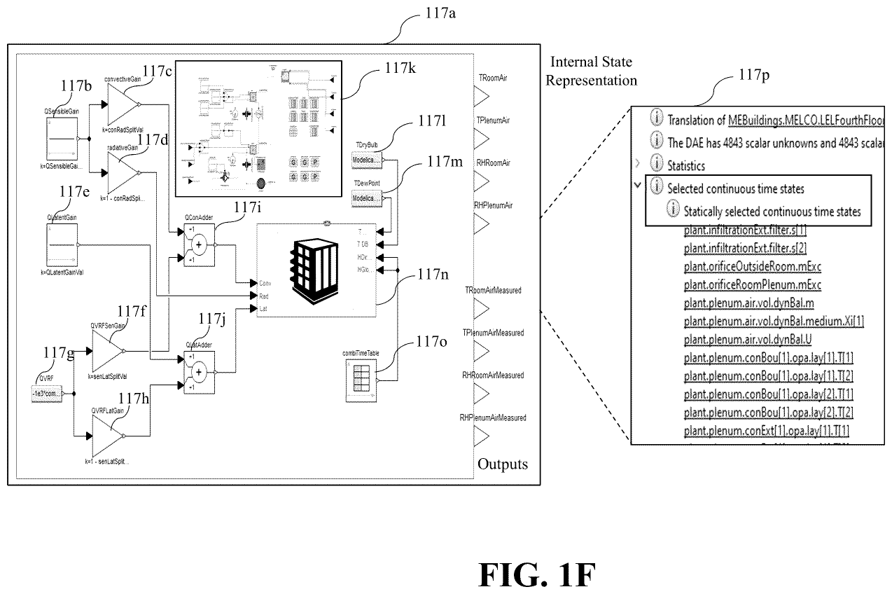

Based on such realizations, the present disclosure provides a device for controlling the system using the internal states of the digital twin, as described below in FIG. 1A.

FIG. 1A illustrates a block diagram of a device 101 for controlling a system 103, according to some embodiments of the present disclosure. The system 103 may be a vapor compression system, a robotic manipulator, or the like. The system 103 is configured to perform a task. For example, the system 103 is the robotic manipulator and the robotic manipulator is configured track a reference trajectory for performing a task of moving an object to a target location. In another example, the system 103 is the vapor compression system and the vapor compression system is configured to maintain an environment at a target temperature.

The system 103 is communicatively coupled to a digital twin 105. The digital twin 105 is a digital representation of the system 103 that serves as an effectively indistinguishable digital counterpart of physical twin, i.e., the system 103. The system 103 and the digital twin 105 operate concurrently. The digital twin 105 is configured to concurrently simulate an operation of the system 103. In other words, the digital twin 105 concurrently simulates real-time operation of the system 103. The system 103 and the digital twin are communicatively coupled to the device 101 via wired or wireless communication.

The device 101 includes a transceiver 107, a processor 109, and a memory 111. The processor 109 may be a single core processor, a multi-core processor, a computing cluster, or any number of other configurations. The memory 111 may include random access memory (RAM), read only memory (ROM), flash memory, or any other suitable memory systems. Additionally, in some embodiments, the memory 111 may be implemented using a hard drive, an optical drive, a thumb drive, an array of drives, or any combinations thereof. The memory 111 is configured to store a neural network 111a. The neural network 111a is trained to estimate a sequence of internal states of the digital twin 105 mapping a sequence of control inputs to a sequence of outputs. The neural network 111a is used to estimate a current internal state of the digital twin and perform the task using the current internal state of the digital twin 105, as described below with reference to FIG. 1B.

FIG. 1B illustrates a block diagram for performing the task using the current internal state of the digital twin 105, according to some embodiments of the present disclosure. At block 110, the processor 109 is configured to collect a sequence of control inputs for controlling the system 103. For example, in an embodiment, the transceiver 107 is configured to submit the sequence of control inputs to the system 103. In a case, where the system 103 is the vapor compression system, the sequence of control inputs includes one or a combination of a speed of a compressor, a speed of a fan, a position of an expansion valve of the vapor compression system. In a case, where the system 103 is the robotic manipulator, the sequence of control inputs includes voltages and/or currents to actuators of the robotic manipulator. The sequence of control inputs changes states of the system 103 according to the task. For example, the sequence of control inputs changes a position of the robotic manipulator towards the target location to perform the task. In another example, the sequence of control inputs changes a current temperature of the environment to the target temperature.

Further, at block 120, the processor 109 is configured to collect a sequence of outputs of the system 103 caused by the corresponding sequence of control inputs. For instance, to collect the sequence of outputs of the system 103, the transceiver 107 is configured to receive a feedback signal including a corresponding sequence of measurements. Each measurement is indicative of an output of the system caused by the corresponding control input. For example, the measurements include temperature, humidity, and/or velocity of air outputted by the vapor compression system. In another example, the measurements include the position of the robotic manipulator. The measurements are collected from one or more sensors associated with the system 103.

At block 130, the processor 109 is configured to estimate the current internal state of the digital twin 105 using the neural network 111a. At block 140, the processor 109 is configured to perform the task using the current internal state of the digital twin 105. In an embodiment, to perform the task using the current internal state of the digital twin 105, a feedback controller is used.

FIG. 1C shows a block diagram of the device 101 including a feedback controller 150, according to some embodiments of the present disclosure. The feedback controller 150 is configured to determine, based on the current internal state of the digital twin 105, a current control input for controlling the system 101. Further, the feedback controller 150 controls the system 101 based on the determined control input to perform the task.

Additionally, in some embodiments, the feedback controller 150 is configured to concurrently control the system 103 and the digital twin 105 based on the determined control input, as described below in FIG. 1D.

FIG. 1D illustrates concurrent control of the system 103 and the digital twin 105, according to some embodiments of the present disclosure. Based on the determined control input, the feedback controller 150 concurrently controls the system 103 to update the state of the system 101 and the digital twin 105 to update the internal states of the digital twin 105.

As the digital twin 105 generates the same outputs as the system 103 through the change of their internal states, the internal states of the digital twin 105 can be used to determine the control input that leads to the desired output. Further, because the internal state is an accurate representation of the operation of the system 103 than the measurements, the feedback control of the system 103 based on the internal states of the digital twin 105 is accurate than the feedback control based on the measurements of the system 103.

In one embodiment, the feedback controller 150 is implemented by a Proportional Integral Derivative (PID) controller. In another embodiment, the feedback controller 150 is implemented by an extremum-seeking control. In yet another embodiment, the feedback controller 150 is implemented by a Model Predictive Control (MPC).

Some embodiments are based on the recognition that in some situations, the digital twin 105 is designed as a black box, such that the internal states of the digital twin 105 are not readily available online during the control of the system 101. However, in contrast with the system 101, the internal states of the digital twin are well-defined, even if the values of the internal state are unknown. Hence, it is possible to learn, online, the internal states of the digital twin 105 from one or a combination of inputs and outputs of the digital twin 105, as described below in FIG. 1E.

FIG. 1E shows a block diagram for online learning of the internal states of the digital twin 105, according to some embodiments of the present disclosure. The digital twin 105 is communicatively coupled to an edge platform 113 and a cloud platform 115. The edge platform 103 is communicatively coupled to the system 103. The digital twin 105 includes a digital twin adaptation module 105a and a digital twin simulation module 105b. The edge platform 113 includes sensors 113a, a decision making module 113b, and an application module 113c. The cloud platform 115 includes a storage media 115a, a data analysis module 115b, and an application module 115c. The application module 115c and the application module 113c may be configured for one or more applications, such as, set-point tracking, model prediction, and anomaly detection.

The digital twin 105 is a high-fidelity simulation software injected with expert-driven, domain-informed modules in addition to learning frameworks that adapt to operational data in order to accurately reflect the system's 103 dynamics. In other words, the digital twin 105 is a digital object that reflects basic properties of an observable physical object. The digital twin 105 can perform monitoring and control functions by connecting to physical world and basic functions of the observable physical object. The digital twin 105 can adapt to alterations in properties of the system 103 by learning from measured outputs of the observable physical object, for example, through use of machine learning. For instance, the sensors 113a output measured data including measurements of the output of the system 103, and the storage media 115a stores data related to intrinsic properties of the system 103 and its environment e.g. exogenous inputs or disturbances. The intrinsic properties include an architecture of a building where the vapor compression system is installed, material properties of the building, occupancy information, environmental information, and user's personalized profile information e.g. how occupants use appliances/water heating/air-con/lights in the building. The data analysis module 115b extracts features from the data stored in the storage media 115a. The measured data and the extracted features are input to the digital twin adaptation module 105a. The digital twin adaptation module 105a comprises machine learning mechanisms that leverage the extracted features and the measured data to update/learn the internal states of the digital twin 105.

The learned or updated internal states of the digital twin are used to initialize the simulation of the operation of the system 103 by the digital twin simulation module 105b. The digital twin simulation module 105b is configured to output simulated data that includes prediction of behavior of the system 103 (i.e., prediction of a state variable of the system 103), given measurements, inputs, and an initial state of the system 103. The simulated data is input to the decision making module 113b. Based on the simulated data, the decision making module 113b determines control inputs to perform concurrent control of the system 103 and the digital twin 105. For instance, the system 103 is controlled based on the control inputs to update the state of the system 103. Further, the digital twin 105 is also controlled based on the control inputs to update the internal states of the digital twin 105. Alternatively, in some embodiments, the decision making module 113b analyzes, based on the simulated data, the behavior of the system 103 under different simulated scenarios for predictive analytics and maintenance. An example implementation of the digital twin simulation module 105b for a building energy system is described below in FIG. 1D.

FIG. 1F illustrates a software implementation of the digital twin simulation module 105b for the building energy system, according to some embodiments of the present disclosure. 117a is a specific implementation of the digital twin of the building energy system in Modelica, capable of injecting sensible heat load 117b and latent heat load 117e, along with the sensible heat load split into convective heat load 117c and radiative heat load 117d. Cooling is provided by a VRF system 117g-j, with building thermal dynamics represented by 117n, with dry and wet bulb ambient temperatures passed from weather data files and additional environmental inputs to the digital twin 117l-o. 117k illustrates the software tools to generate the thermal dynamics of the building 117n. As evident from 117p, the software has generated its own realization of continuous-time digital twin states that may not have closed-form analytical expressions.

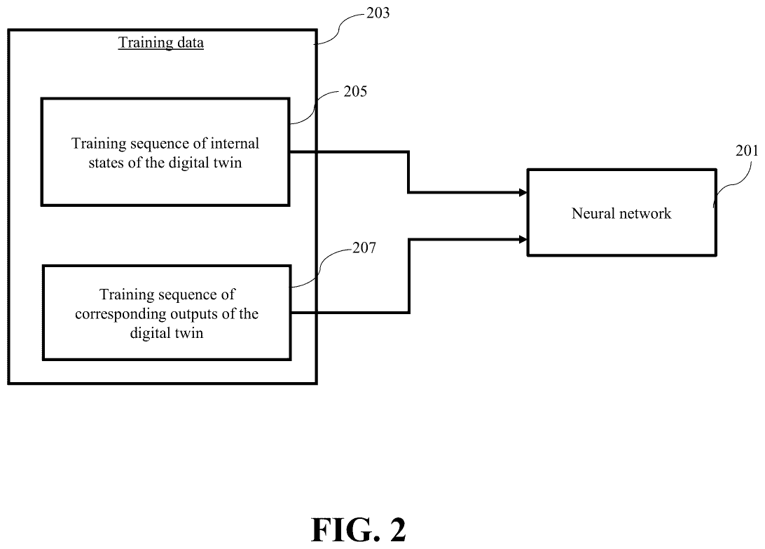

FIG. 2 illustrates training of a neural network 201 for estimating the sequence of internal states of the digital twin 105, according to some embodiments of the present disclosure. The neural network 201 corresponds to the neural network 111a stored in the memory 111. The neural network 201 is trained with supervised learning based on training data 203. The training data 203 includes a training sequence 205 of internal states of the digital twin and the control inputs given to the digital twin, and a training sequence 207 of corresponding outputs of the digital twin. The neural network 201 is trained with the supervised learning based on the training data 203 to map the outputs of the digital twin 105 to the internal states of the digital twin causing the outputs of the digital twin 105.

In some embodiments, the neural network 201 is trained offline, i.e., in advance, and the trained neural network 201 is executed online, i.e., during real-time operation, to estimate the current internal state of the digital twin 105. For example, the processor 109 is configured to execute the trained neural network 201 to estimate the current internal state of the digital twin 105 during real time operation.

In some embodiments, the neural network 201 is a neural network having an autoencoder architecture. In other words, the neural network 201 is an autoencoder. Some embodiments are based on the understanding that the autoencoder can be used to learn transformations that ‘lift’ dynamics of the system 101 to a latent space where a finite-dimensional linear state-space model can provide an accurate predictive model. The benefit of the autoencoder is that state observer design can leverage a linear system representation and classical observer gain tuning methods can be applied. In addition, effectiveness of learning lifting transformations in nonlinear system identification can be linked to Koopman operator-theoretic designs, where a linear state-transition operator learned by the autoencoder represents a finite approximation of the Koopman operator.

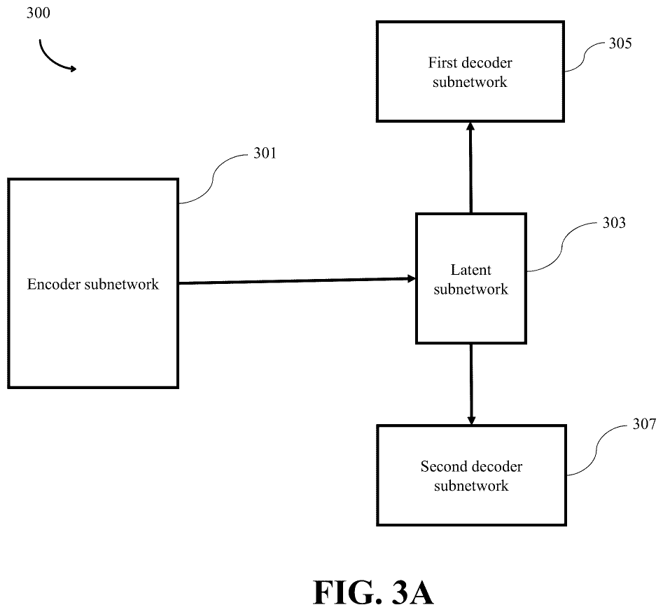

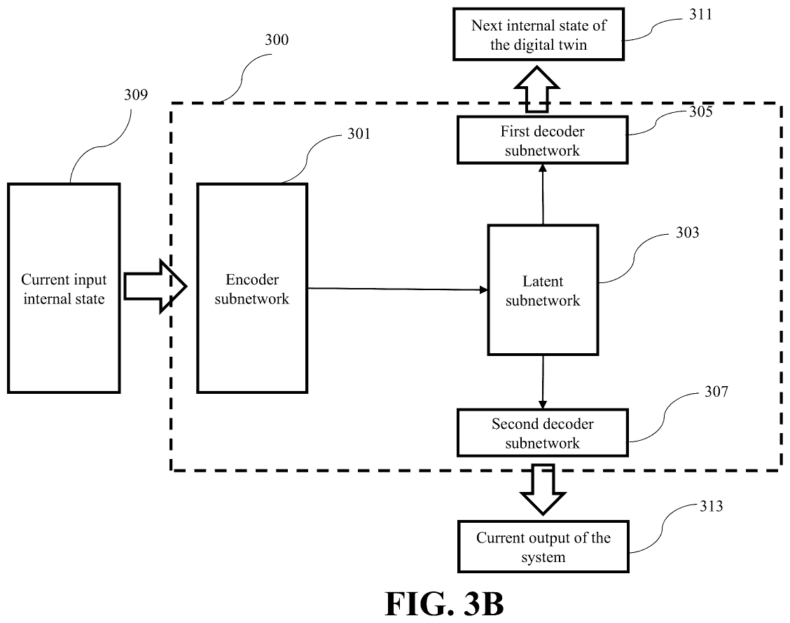

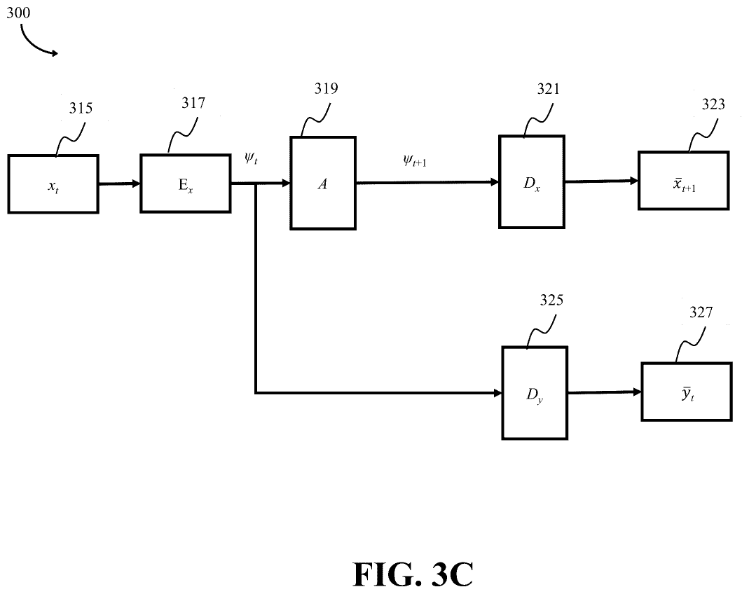

In such a manner, the autoencoder can be advantageously used for learning of the internal states of the digital twin 105. To that end, some embodiments use an autoencoder having a latent space adapted for dynamic propagation of encodings of the internal states of the digital twin 105 within a prediction horizon into decodings indicative of a combination of the internal states of the digital twin 105 and outputs (measurements) of the system 101. Such an autoencoder is described in detail in FIG. 3.

FIG. 3A illustrates an autoencoder 300, according to some embodiments of the present disclosure. The autoencoder 300 includes an encoder subnetwork 301, a latent subnetwork 303, a first decoder subnetwork 305, and a second decoder subnetwork 307. A current input internal state is input to the autoencoder 300. Based on the current input internal state, the autoencoder 300 outputs the next internal state of the digital twin 105 and current output of the system 101, as described below with reference to FIG. 3B.

As shown in FIG. 3B, a current input internal state 309 is input to the encoder subnetwork 301. The encoder subnetwork 301 is configured to encode the current input internal state 309 into latent space to produce a current encoding of the internal state in the latent space. The current encoding of the internal state in the latent space is input to the latent subnetwork. The latent subnetwork 303 is configured to propagate the current encoding of the internal state in the latent space forward in time to produce a next encoding of the internal state in the latent space. Further, the next encoding of the internal state in the latent space is input to the first decoder 305. The first decoder subnetwork 305 is configured to decode a next internal state 311 of the digital twin 105 from the next encoding of the internal state in the latent space. The second decoder subnetwork 307 configured to decode a current output of the system 101 from the current encoding of the internal state in the latent space.

Some embodiments are based on the realization that it is advantageous to design a control law of the feedback controller 150 using the latent space of the autoencoder 300, as such a design allows transforming a non-linear control of the system into a linear control in the latent space. To that end, the feedback controller 150 is configured to control the system 103 using a linear control law including a control matrix formed by values of the parameters of the latent subnetwork 303. The latent subnetwork 303 is trained to perform linear propagation of the encodings of the internal state.

In some embodiments, the processor 109 is configured to solve an optimization problem that produces a sequence of the internal states within a prediction horizon that is transformed by the autoencoder 300 to match the sequence of outputs of the system 103. The autoencoder 300 and the optimization problem are mathematically described below.

The digital twin 105 with internal dynamics is defined as

$${x}_{t + 1} = f ( {x}_{t} ) , \qquad ( 1 a )$$

$${y}_{t} = h ( {x}_{t} ) , \qquad ( 1 b )$$

where t∈N is time-index, x∈Rⁿ^{ₓ} is the internal state, y∈Rⁿ^{_{y}} is the measured output of the system 101, and f, h are unmodeled state update and output functions, respectively. The dynamics (1) are unknown to the designer, but it is assumed that f and h exist and are well-defined. It is assumed that the system response is bounded from any initial condition x∈Rⁿ^{ₓ}, and that f and h are such that the state x is observable from the output y.

Unlike classical input-output system identification where concept of a state is selected by the designer, in simulator-driven identification the state-space is fixed by the digital twin 105, and the outputs are nonlinear functions of the states fixed by the digital twin 105. State-feedback controllers designed on the digital twin 105 require the states x online, but the states are typically not measured, and therefore have to be estimated from only the measurement outputs y.

To that end, it is an objective some embodiments to estimate the states {x}_{t≥0} online from the outputs {y}_{t≥0}, based on a representation of the dynamics (1) learned using dataset Dₜᵣₐᵢₙ≙{(xₜ, yₜ)}_{t⊂N}. The dataset comprises state-output pairs collected by offline simulations of the digital twin 105. Some embodiments leverage an autoencoder (such as autoencoder 300) to estimate the states x.

FIG. 3C illustrates an example implementation of the autoencoder 300, according to some embodiments of the present disclosure. The input to the autoencoder 300 is a state xₜ 315, which is passed through an encoder Eₓ 317 (e.g., encoder subnetwork 301) to compute a latent encoding ψₜ∈Rⁿ^{_{ψ}}. The latent encoding is updated using a linear state-transition operator A: n_{ψ}′→n_{ψ} 319. The updated latent ψₜ₊₁ is passed through a state-decoder Dₓ 321 (e.g., first decoder subnetwork 305) that returns a state estimate x̅ₜ₊₁ 323. A separate decoder D_{y} 325 (e.g., second decoder subnetwork 307) generates an estimate y̅ₜ 327 of the output yₜ based on the latent variable ψₜ. That is,

$${ψ}_{t} = {E}_{x} ( {x}_{t} ) , \qquad ( 2 a )$$

$${ψ}_{t + 1} = A ( {ψ}_{t} ) , \qquad ( 2 b )$$

$${\overline{x}}_{t + 1} = {D}_{x} ( {ψ}_{t + 1} ) = {D}_{x} ∘ A ∘ {E}_{x} ( {x}_{t} ) , \qquad ( 2 c )$$

$$\overline{y} = {D}_{y} ( {ψ}_{t} ) = {D}_{y} ∘ {E}_{x} ( {x}_{t} ) . \qquad ( 2 d )$$

In an embodiment, the operator A 319 and the decoder D_{y} 325 can be enforced to be state-transition and output matrices, respectively, by selecting them to be linear layers with zero bias. The state-transition operator A 319 can be viewed as a Koop-man operator that enables a linear description of the non-linear dynamics (1) in high-dimensional latent space.

According to some embodiments, the autoencoder 300 is trained to minimize a loss function of a difference of the combination of the internal states of the digital twin 105 and the outputs of the digital twin 105 over a prediction horizon. Training of the autoencoder 300 involves computing weights of the encoder Eₓ 317, the two decoders Dₓ 321 and D_{y} 325, and the state transition operator A 319. To this end, a multi-step reconstruction loss with regularization is used. Formally, at index t, the current state xₜ can be selected as the input and a window of length Ĥ of current/future states can be selected

$${X}_{t + 1 : t + \hat{H}} = \{ {x}_{t + 1} , {x}_{t + 2} , … , {x}_{t + \hat{H}} , \} ,$$

along with the future outputs

$${y}_{t + t : \hat{H} - 1} = \{ {y}_{t + 1} , {y}_{t + 2} , … , {y}_{t + \hat{H} - 1} , \} ,$$

using the dataset Dₜᵣₐᵢₙ. Subsequently, with xₜ, X̅_{t+1:t+Ĥ}, and Y̅_{t+t:Ĥ-1} are estimated using the autoencoder (2a)-(2d).

The loss function is described as follows: [symbol] ₜ_{₁}_{:t}_{₂}={qₜ_{₁}, . . . , qₜ, . . . , qₜ₂} denote any tensor with q_{τ}∈Rⁿ^{_{q}}, along with its estimate [symbol] _{t1:t2}.

Then,

$$MSE ( {t 1 : t 2}_{} , {\hat{Q}}_{t 1 : t 2.} ) {=}^{△} \frac{1}{{n}_{q} ( {t}_{2} - {t}_{1} )} {\sum }_{τ = {t}_{1}}^{{t}_{2}} {‖ {q}_{τ} - {\hat{q}}_{τ} ‖}_{2}^{2} .$$

For training, the following loss function is minimized

$$ℓ = {ℓ}_{recon} + {ℓ}_{pred , X} + {ℓ}_{pred , Y} + {λ}_{reg} {ℓ}_{reg} , \qquad ( 3 )$$

where the first three terms are mean-squared-error (MSE) losses, with

$${ℓ}_{recon} = MSE ( {x}_{t} , {D}_{x} ∘ {E}_{x} ( {x}_{t} ) ) ,$$

denoting a reconstruction loss of the autoencoder without a state update,

$${ℓ}_{pred , X} = MSE ( {X}_{t + 1 : t + \hat{H}} , {\overline{X}}_{t + 1 : t + \hat{H}} )$$

denoting the multi-step prediction error on the states of the system 101, and

$${ℓ}_{pred , Y} = MSE ( {Y}_{t + t : \hat{H} - 1} , {\overline{Y}}_{t + t : \hat{H} - 1} )$$

is a multi-step prediction error computed over the outputs. The operator A is penalized via L₁ regularization loss

$${ℓ}_{reg} = {‖ A ‖}_{2}$$

with regularization coefficient λ_{reg}>0 to inject stability to the learned A.

At each time index t, given a H-length window of measurements Y_{t:t+H}, the state xₜ is estimated by solving the following optimization problem,

$${min}_{{X}_{t - H : t}} {\sum }_{τ = 0}^{H - 1} {‖ {δ}_{τ}^{x} ‖}_{{Q}_{f}}^{2} + {‖ {δ}_{τ}^{y} ‖}_{{R}_{f}}^{2} \qquad ( 4 a )$$

subject to:

$${\overline{y}}_{t - τ} = {D}_{y} ∘ {E}_{x} ( {x}_{t - τ} ) . ∀ τ ∈ {N}_{0 : H} \qquad ( 4 b )$$

$${\overline{x}}_{t - τ + 1} = {D}_{x} ∘ A ∘ {E}_{x} ( {x}_{t - τ} ) , ∀ τ ∈ {N}_{0 : H} \qquad ( 4 c )$$

$${δ}_{τ}^{x} = {\overline{x}}_{t - τ} - {x}_{t - τ} \qquad ( 4 d )$$

$${δ}_{τ}^{y} = {\overline{y}}_{t - τ} - {y}_{t - τ} \qquad ( 4 e )$$

where N_{a:b} is a set of natural numbers between and including a, b∈N. To solve optimization problem (4a)-(4e), a sequence of state estimates {x_{t-τ}}^{H} that minimizes a weighted sum of state and output prediction errors is generated. The state prediction error is defined in (4d) using deviations between the generated state estimates and one-step predictions using (4c). The output prediction error is defined in (4e) using deviation between the measurements and outputs estimated using (4b). Of [symbol] [symbol] 0 and R_{ƒ} [symbol] 0 in (4a) are weighting matrices to enforce preferences over specific state dimensions.

Since the encoder and decoder transformations may be nonlinear, the optimization problem (4a)-(4e) is a nonlinear least squares problem. The optimization problem (4a)-(4e) may be solved using limited memory BFGS implemented using automatic differentiation that leverages the PyTorch library. Alternatively, optimization problem (4a)-(4e) may be solved using standard nonlinear least squares techniques like Levenberg-Marquardt algorithms or nonlinear moving horizon estimators using the identified nonlinear dynamics.

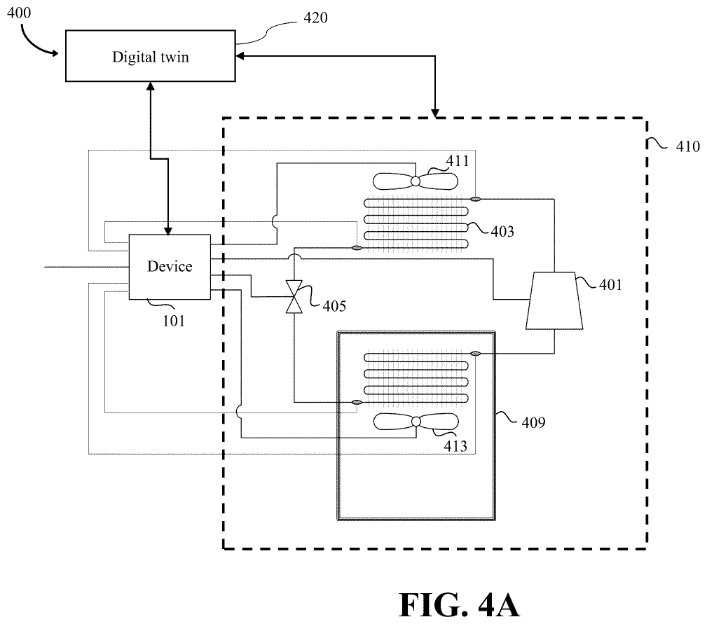

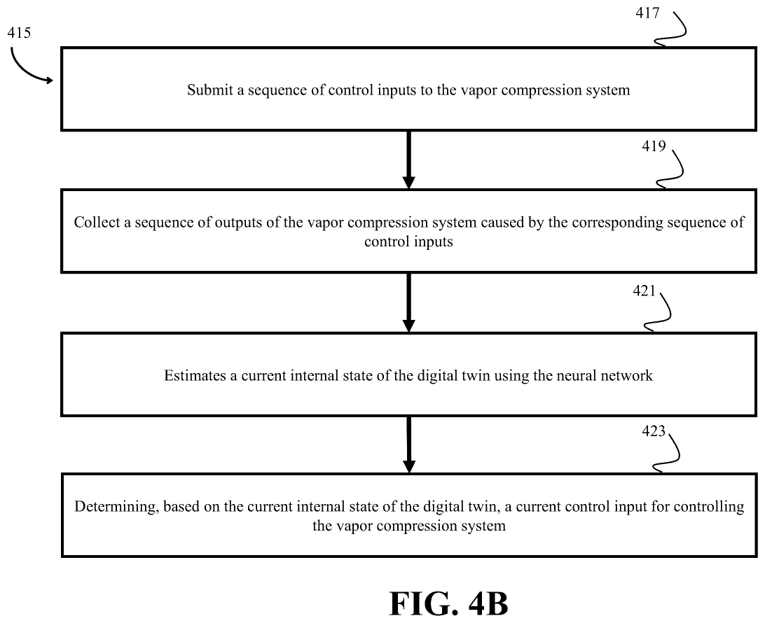

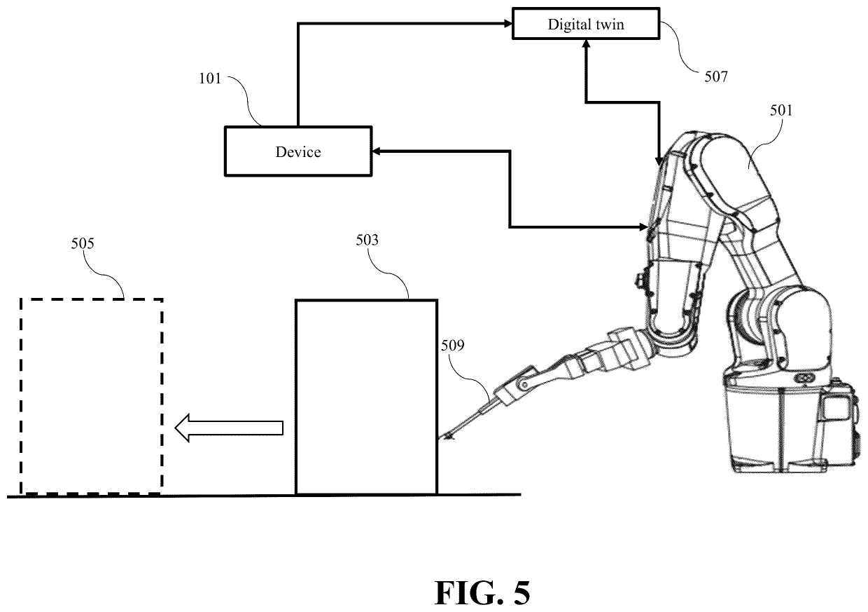

Next, use cases of the device 101 are explained in FIG. 4A, FIG. 4B, and FIG. 5. The device 101 can be used to control an operation of the vapor compression system. Additionally or alternatively, the device 101 can be used to control an operation of the robotic manipulator. Controlling of the vapor compression system using the device 101 is explained in FIG. 4A and FIG. 4B. Controlling of the robotic manipulator using the device 101 is explained in FIG. 5

FIG. 4A illustrates an environment 400 for controlling a vapor compression system 410, according to some embodiments of the present disclosure. The environment 400 includes the vapor compression system 410, a digital twin 420 of the vapor compression system 410, and the device 101. The vapor compression system 410 and the digital twin 420 are communicatively coupled to the device 101. The vapor compression system is configured to perform a task of maintaining an environment at a target state. The target state may include a target temperature.

The vapor compression system 410 includes a compressor 401, a condensing heat exchanger 403, an expansion valve 405, and an evaporating heat exchanger 407 located in a space 409. Heat transfer from the condensing heat exchanger 403 is promoted by use of a fan 411, while heat transfer from the evaporating heat exchanger 407 is promoted by use of a fan 413. The vapor compression system 410 may include variable actuators, such as a variable compressor speed, a variable expansion valve position, and variable fan speeds. There are many other alternate equipment architectures to which the present disclosure pertains with multiple heat exchangers, compressors, valves, and other components such as accumulators or reservoirs, pipes, and so forth, and the illustration of the vapor compression system 410 is not intended to limit the scope or application of the present disclosure to systems whatsoever.

In the vapor compression system 410, the compressor 401 compresses a low pressure, low temperature vapor-phase fluid (a refrigerant) to a high pressure, high temperature vapor state, after which it passes into the condensing heat exchanger 403. As the refrigerant passes through the condensing heat exchanger 403, the heat transfer promoted by the fan 411 causes the high-temperature, high pressure refrigerant to transfer its heat to ambient air, which is at a lower temperature. As the refrigerant transfers the heat to the ambient air, the refrigerant gradually condenses until the refrigerant is in a high pressure, low temperature liquid state. Further, the refrigerant leaves the condensing heat exchanger 403 and passes through the expansion valve 405, and expands to a low pressure boiling state from which it enters the evaporating heat exchanger 407. As air passing over the evaporating heat exchanger 407 is warmer than the refrigerant itself, the refrigerant gradually evaporates as it passes through the evaporating heat exchanger 407. The refrigerant leaving the evaporating heat exchanger 407 is at a low pressure, low temperature state. The low pressure, low temperature refrigerant re-enters the compressor 401 and the same VCS is repeated.

FIG. 4B shows a block diagram of a method 415 for controlling the vapor compression system 410, according to some embodiments of the present disclosure. At block 417 of the method 415, the transceiver 107 of the device 101 submits a sequence of control inputs to the vapor compression system 410. The sequence of control inputs includes one or a combination of a speed of a compressor 401, a speed of the fan 413, and a position of the expansion valve 405 of the vapor compression system 410.

At block 419 of the method 415, the transceiver 107 of the device 101 receives a collect a sequence of outputs of the vapor compression system 410 caused by the corresponding sequence of control inputs. The sequence of outputs of the vapor compression system 410 may correspond to a sequence of measurements. Each measurement is indicative of an output of the vapor compression system 410 caused by the corresponding control input. For example, the measurements include temperature, humidity, and/or velocity of air outputted by the vapor compression system 410.

At block 421 of the method 415, the processor 109 of the device 101 estimates a current internal state of the digital twin 420 using the neural network 111a.

At block 423 of the method 415, the feedback controller 150 of the device 101 determines, based on the current internal state of the digital twin 420, a current control input for controlling the vapor compression system 410. The current control input is submitted to the vapor compression system 410. The current control input changes a current state to the target state. For instance, the current control input change a current temperature to the target temperature to perform the task of maintaining the target temperature.

FIG. 5 illustrates a method for controlling of a robotic manipulator 501 using the device 101, according to some embodiments of the present disclosure. The robotic manipulator 501 is configured to perform a manipulation task of moving an object 503 to a target state 505, e.g., a target location. The robotic manipulator 501 is communicatively coupled to the device 101 and a digital twin 507 of the robotic manipulator 501.

The transceiver 107 of the device 101 submits a sequence of control inputs to the robotic manipulator 501. The sequence of control inputs includes voltages and/or currents to actuators of the robotic manipulator 501. Further, the transceiver 107 of the device 101 collects a sequence of outputs of the robotic manipulator 501 caused by the corresponding sequence of control inputs.

Further, the processor 109 of the device 101 estimates a current internal state of the digital twin 507 using the neural network 111a. Furthermore, the feedback controller 150 of the device 101 determines, based on the current internal state of the digital twin 507, a current control input for controlling the robotic manipulator 501. The feedback controller 150 controls the actuators of the robotic manipulator 501 according to the current control input, causing the end-effector 509 to push the object 503 from a current state to the target state 505.

### Exemplar Embodiments for State Estimation Using Physics-Constrained Machine Learning

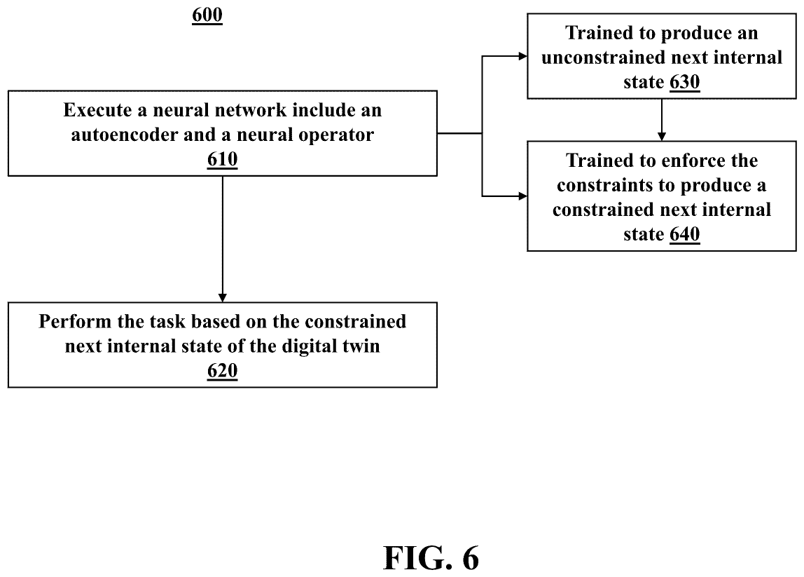

FIG. 6 shows a block diagram of method 600 for performing a task based on an internal state of a digital twin simulating control of an operation of a mechanical system according to some embodiments. At least some state variables of the internal states of the digital twin are subject to constraints derived from the physics of a structure of the mechanical system. For example, in some embodiments, the mechanical system is a vapor compression system (VCS), and the constraints mandate the internal states of the digital twin of the VCS to satisfy decreasing pressure in the direction of refrigerant flow in the VCS. Additionally, or alternatively, the constraints may define box constraints, i.e., upper and lower bounds on the physical states of a digital twin. For example, the constraints can specify that density must be positive.

In various embodiments, method 600 uses a processor coupled with stored instructions implementing the method, wherein the instructions, when executed by the processor carry out steps of the method, The method is configured to execute 610 a neural network including an autoencoder trained 630 to process a current internal state of the digital twin and a current control input to the mechanical system to produce a current output of the mechanical system caused by the current control input and an unconstrained next internal state of the digital twin transitioned from the current internal state based on the current control input, and a neural operator trained 640 to modify the unconstrained next internal state of the digital twin to produce a constrained next internal state of the digital twin satisfying the constraints.

The method is configured to perform 620 a task based on the constrained next internal state of the digital twin. In the context of VCS, examples of the task include one or a combination of an estimation of heating/cooling capacities delivered by the VCS to a space, a computation of refrigerant mass in the VCS, control of the VCS, a performance monitoring of the operation of the VCS, anomaly detection in the operation of the VCS, a model predictive control of the VCS.

Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

Some embodiments are based on realizing that the module that enforces the constraints on the internal states of the digital twin can be implemented as a neural operator. A neural operator refers to the use of neural networks to approximate or learn an operator in mathematical terms. Some embodiments use a neural operator to learn and approximate mathematical formulations enforcing the satisfaction of the constraints. As a result, a separation of the function of the autoencoder estimating unconstrained internal states of the digital twin and the neural operator enforcing the constraints enables a single neural framework having the advantages of the statistical nature of the neural network allowing to use of this neural framework in subsequent statistical operations such as tracking the internal states of the digital twin with a probabilistic filter, such as a Kalman filter.

A neural operator can be trained jointly with the autoencoder to ensure the efficiency of the performance of various statistical operations. Notably, the ability of the neural operator to enforce the constraints can be used independently from the autoencoder. However, when the neural operator is jointly trained on the outputs of a decoder of the autoencoder, it is beneficial to keep enforcing the constraints on the outputs of the autoencoder rather than on independently derived unconstrained internal states. This is because the neural operator is partially analytical and partially data-driven. The constraint enforcement part is analytical enabling exact satisfaction of the constraints. However, the map from unconstrained space to the nonnegative orthant that is used in analytical satisfaction of the constraints is a neural layer whose weights are trained using machine learning methods. To that end, in some embodiments, the neural operator is jointly trained with the autoencoder.

As a result, the autoencoder and the neural operator provide a joint framework for estimating the internal states of the digital twin that satisfy the constraints while using the benefits of machine learning and enjoying the guarantees of mathematical formulations.

For example, in some implementations, the constraint is a linear inequality Gx≤0, in terms of the internal states x and an appropriately defined matrix G.

The polytope [symbol] defined by the inequality Gx≤0,

$$= \{ x ∈ {R}^{n} : Gx \leq 0 \}$$

Is equivalent to the following rays-based description

$$= cone ( ) := μ$$

Where, [symbol] ∈R^{n×r} is the matrix containing rays that describe the polytope [symbol] , and 0≤μ∈R^{r} is a nonnegative vector compatible with dimension of the rays matrix.

The neural operator encodes the constraint Gx≤0, using an equivalent rays-based description of a polytope defined by the linear inequality, such that the unconstrained decoding of the next internal state is passed through a fully connected (FC) neural layer which produces a nonnegative vector of a dimension that is compatible with the matrix of rays describing the polytope, and the product of the nonnegative vector with the matrix of rays results in the next internal state satisfying the constraint.

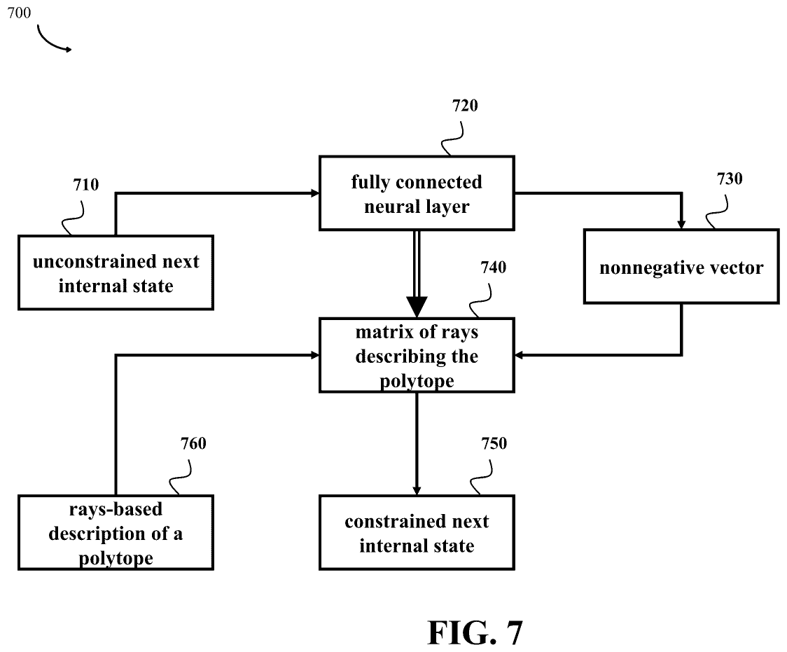

FIG. 7 shows a schematic of a neural operator used by some embodiments. In these embodiments, the constraints define a linear inequality in terms of the internal states. The neural operator encodes the constraints using an equivalent rays-based description 760 of a polytope defined by the linear inequality, such that the unconstrained next internal state 710 is passed through a fully connected neural layer 720 which produces a nonnegative vector 730 of a dimension compatible with a matrix 740 of rays 760 describing the polytope, and a product of the nonnegative vector 730 with the matrix 740 of rays results in the constrained next internal state 750 satisfying the constraints.

In some cases, the mechanical system is VCS, and for clarity, the description of some embodiments is written with respect to a task associated with the operation of the VCS. However, the embodiments can be readily extended to different types of mechanical systems, such as robots and robotic manipulators.

A state vector of VCC is a set of variables that mathematically represent a complete description of the underlying physical system. A state vector may include physical variables such as pressure and temperature in different components of the VCS. Accurate estimation of states of VCSs is beneficial for many technological solutions including control, performance monitoring and optimization, and broader digital twin applications. State-of-the-art state estimation approaches used in VCC applications combine operational data such as sensor measurements collected from the VCS with the predicted states of the VCC in order to accurately estimate the state vector. Predicted states of a VCC are typically obtained from computational models which are derived from the fundamental physical laws that govern different components of the VCS and the overall VCS dynamics.

Such physics-based computational models of VCCs enable high-fidelity simulations but typically require a high-dimensional state representation. Furthermore, the underlying VCC dynamics are numerically stiff, constrained by physical conservation laws, and only a small fraction of the states can be measured online. Consequently, major bottlenecks to efficient implementations of state estimation methods include (i) expensive forward model predictions requiring customized stiff numerical solvers; and, (ii) frequent and computationally expensive linearization operations on high-dimensional nonlinear models.

Therefore, it is an objective of some embodiments to develop a system and method to construct surrogate neural state-space models (NSSMs) from simulation data for which both forward predictions and linearization operations via automatic differentiation can be performed efficiently; and to use these surrogate NSSMs for state estimation of VCCs.

The simulation data needed to learn the surrogate NSSM is collected from a high-fidelity VCS model or digital twin which can be represented as follows.

$${x}_{k + 1} = f ( {x}_{k} , {u}_{k} ) ,$$

$${y}_{k} = h ( {x}_{k} ) ,$$

Where xₖ is the state vector, uₖ is the vector of control inputs to the VCS, and yₖ is the vector of outputs that can be measured from the physical system. The function ƒ predicts the state vector at time step k+1 for a given state and control input at time step k, whereas, function h maps the state vector to the output variables. The functions ƒ and h are often not accessible to the user, as they may be represented in high-fidelity simulation software such as ‘digital twins’ that contain black-box components. Therefore, a surrogate NSSM is learned from simulation data collected from this black-box model. The simulation data or training data comprises of trajectories collected over N time steps, i.e.,

$${D}_{train} = {\{ {x}_{k} , {y}_{k} , {u}_{k} \}}_{k = 0}^{N} .$$

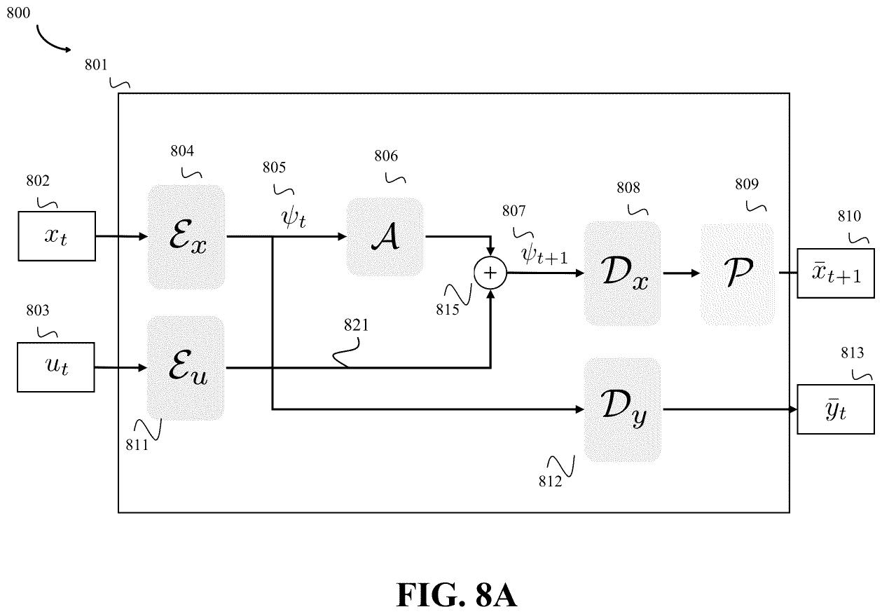

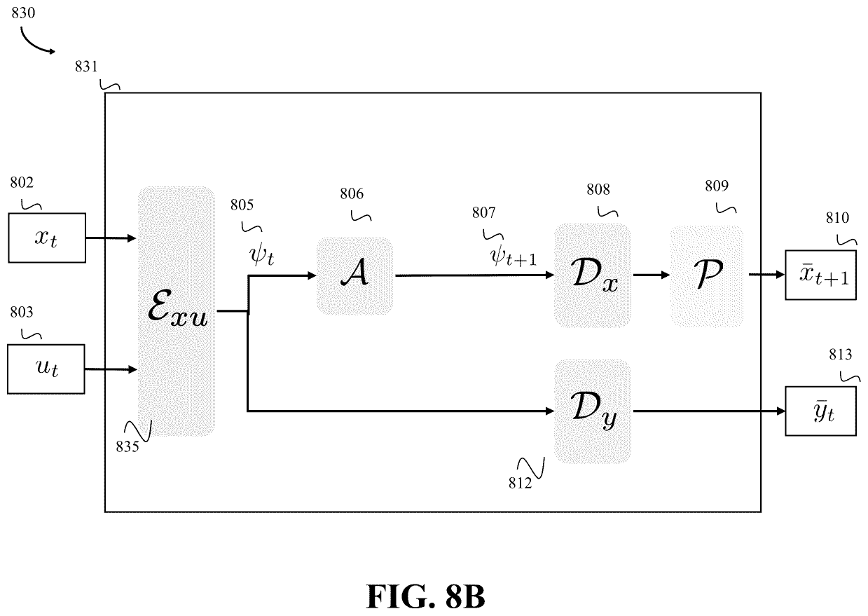

FIG. 8A shows a schematic of an auto-encoder-based architecture of NSSM according to some embodiments. The NSSM 801 takes in the current state vector xₖ 802 and controls uₖ 803 as inputs; and outputs the reconstructed state prediction step xₖ₊₁ 810 at the next time and the reconstructed output vector [symbol] 813. While the operators εₓ 804 and εᵤ 811 encode the physical states into the latent representation ψₖ 805, the operators [symbol] ₓ 808 and [symbol] [symbol] 812 decode the latent representation 805, and 807 to state vector 810 and output vector 813 in the physical domain. The transition operator [symbol] 806 advances the latent representation forward in time. The addition operator 815 adds output of operator [symbol] 806 and the latent representation 821 of control inputs to predict the latent state ψₖ₊₁ 807 at time step k+1.

FIG. 8B shows another variation of an auto-encoder-based architecture of NSSM illustrated FIG. 8A. In this architecture 831, one may replace split encoders εₓ 804 and εᵤ 811 with a single mixed encoder εₓᵤ 835 which transforms the current state vector xₖ 802 and controls uₖ 803 to the latent representation ψₓ 805. The transition operator [symbol] 806 advances the latent representation forward in time to directly predict the latent state ψₖ₊₁ 807 at time step k+1.

One example of a fundamental constraint that VCC states must satisfy is the decreasing pressure in the direction of refrigerant flow in the system. Since high-fidelity VCC models are based on physics, they inherently satisfy this constraint. On the other hand, neural SSMs which are learned only from the data do not guarantee satisfaction of such physical constraints unless they are explicitly embedded in the SSM architecture. Therefore, it is an objective of some embodiments of the present invention to explicitly incorporate pressure gradient constraint in the NSSM architecture using a neural operator, [symbol] 809. The pressure gradient constraint which must be satisfied by a VCC's state vector can be expressed as a linear inequality Gxₖ≤0, where G is an appropriately defined matrix. The operator [symbol] 809 explicitly encodes this constraint using a rays-based description 760 of the feasible polytope as illustrated in 700. In particular, the operator [symbol] 809 can be described as follows

$$= ∘ {𝒟}_{x} ( {ψ}_{k} )$$

$$= μ$$

$$where$$

$$μ = ReLU ∘ FC ∘ {𝒟}_{x} ( {ψ}_{k} )$$

Where [symbol] is the ray-matrix describing the polytope, FC is a fully connected neural layer and rectified linear unit (ReLU) activation function guarantees that the vector μ is nonnegative.

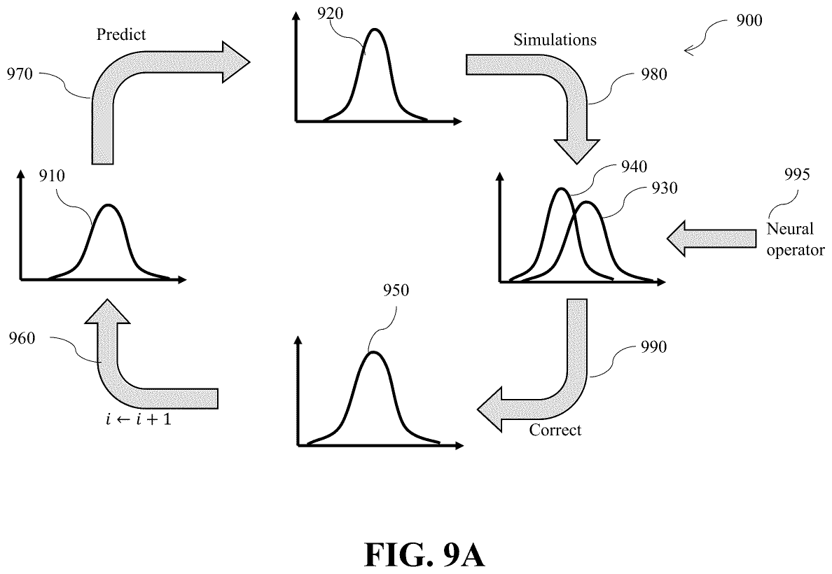

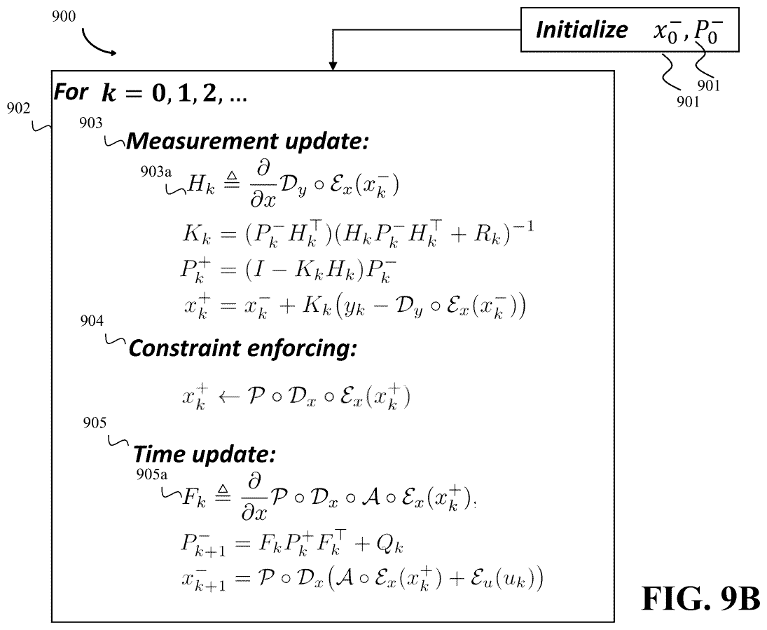

FIG. 9A shows a schematic 900 illustrating the steps executed by the probabilistic filter for estimating the internal states of the digital twin, according to some embodiments of the present disclosure. The probabilistic filter, e.g., a Kalman filter, uses a prediction model subject to process noise and a measurement model subject to measurement noise. At least one of the prediction and measurement models includes the neural network estimating the internal states subject to constraints. As a result, the internal states satisfying the constraints can be implemented using probabilistic guarantees provided by a probabilistic filter.

The steps executed by the probabilistic filter 900 include a prediction step 970, a simulation step 980, and/or a correction step 990. In the prediction step 970, the probabilistic filter estimates a probabilistic distribution function (PDF) 920 of predicted values of the internal states from a PDF 910 of values of the internal states, using a prediction model. For instance, the PDF 920 may correspond to a Gaussian distribution. The Gaussian distribution may be defined by a mean and a variance, where the mean defines a center position of the distribution 920 and the variance defines a spread (or a width) of the distribution 920.

Referring back to FIG. 9A, at least one simulation of the operation of the mechanical system with the measurements indicative of the outputs of the mechanical system at the current control step and a value of the internal states sampled from PDF 920 of predicted values of the internal states is carried out, to produce an estimation 940 of the internal states of the digital twin of the mechanical system. The estimation of the internal states can be further modified 930 by the neural operator 995 to enforce physics-based constraints of the mechanical system. The correction step 990 updates the probabilistic distribution of the internal states 950 initializing the next iteration 960 of the probabilistic filter. The values of the internal states used for performing a task are sampled on the distribution 950.

FIG. 9B shows a pseudo-code of a method for estimating internal states of mechanical systems, such as VCS, according to some embodiments. It is an objective of some embodiments to use the learned NSSM for estimating states of VCC. Accordingly, an extended Kalman filter (EKF) which uses the surrogate NSSM as the prediction model is shown in FIG. 9B.

The EKF uses the following model equations for predictions corresponding to the NSSM architecture 800.

$${x}_{k + 1} = ∘ {𝒟}_{x} ( ∘ {ℰ}_{x} ( {x}_{k} ) + {ℰ}_{𝓊} ( {u}_{k} ) ) + {w}_{k}$$

$${y}_{k} = ∘ {ℰ}_{𝓍} ( {x}_{k} ) + {η}_{k}$$

Where wₖ and ηₖ are, respectively, zero-mean Gaussian process and measurement noise with covariance matrices [symbol] ₖ and Rₖ. The prior and posterior mean-covariance pairs at time k are denoted by (xₖ⁻, Pₖ⁻) and (xₖ⁺, Pₖ⁺), respectively.

The EKF is initialized with a prior distribution (x₀⁻, P₀⁻) 901, and the filtering steps are then executed recursively. The measurement update step 903 combines sensor measurements yₖ collected from the physical system with the priors (xₖ⁻, Pₖ⁻) to obtain the updated posterior state estimates (xₖ⁺, Pₖ⁺).

Standard estimation algorithms such as EKF do not guarantee that the fundamental physical constraints, e.g., pressure gradient constraints, are satisfied by the updated posterior state estimates. However, these physical constraints must be satisfied for the estimated state vector to be physically realizable and consistent with the physics of the system. Some embodiments of the present invention are based on the realization that physics-based constraints must be explicitly incorporated into the estimation process. Accordingly, the EKF includes the constraint enforcing step 904 after the measurement update step 903.

The pressure gradient constraint which must be satisfied by a VCC's state vector can be expressed as a linear inequality Gxₖ≤0. One approach for incorporating such constraints in filtering methods is via projection of posterior state estimate xₖ⁺ on the feasible set. This projection operation involves solving a quadratic program ( [symbol] P) subject to linear inequality constraints. This leads to significant computational overheads since a high-dimensional constrained [symbol] P must be solved at every step of the EKF algorithm.

On the other hand, the NSSM architectures 801 and 831 explicitly incorporate pressure gradient constraints using a neural operator [symbol] 809. Therefore, some embodiments are based on the realization that the constraint-enforcing NSSM architecture can be leveraged to enforce the same constraints in filtering steps. In particular, the encoder εₓ transforms the state vector to latent representation and the constrained-decoder [symbol] o [symbol] ₓ reconstructs a physically constrained state vector from the latent representation. Accordingly, some embodiments of the present invention are based on the realization that the auto-encoder pair (εₓ, [symbol] o [symbol] ₓ) can be used for projecting a state vector on the feasible set defined by pressure gradient constraints, i.e., the state vector can be projected by the following operation

$${x}_{k} ← ∘ {𝒟}_{𝓍} ( {ℰ}_{𝓍} ( {x}_{k} ) )$$

Which is included in the EKF algorithm as the constraint enforcing step 904. The last step of the EKF algorithm is the time update 905 in which the prior state distribution is predicted using the model equations.

The EKF implementation requires model linearization, i.e., computation of Jacobian matrices 903a and 905a of process and measurement models. Although NSSM is a complex mathematical model, its derivatives and Jacobian are efficiently computed using automatic, algorithmic, or computational differentiation methods.

Different embodiments use different implementations of an autoencoder trained to produce unconstrained next states of the mechanical system. For example, in an embodiment shown in FIG. 8A, the autoencoder architecture includes a first encoder subnetwork 804 configured to encode the current internal state 802 into latent space to produce an encoding 805 of the current internal state in the latent space; a second encoder subnetwork 811 configured to encode the current control input 803 into the latent space to produce an encoding 821 of the current control input in the latent space.

The autoencoder also includes a latent subnetwork 806 configured to propagate forward in time one or a combination of the encoding 805 of the current internal state and the encoding 821 of the current control input to produce an encoding 807 of the next internal state in the latent space. For example, the latent subnetwork is configured to propagate the encoding of the current internal state forward in time and combine the propagated encoding of the current internal state with the encoding of the current control input to produce the encoding of the next internal state in the latent space. Additionally, or alternatively, the latent subnetwork is configured to propagate a mix of the encoding of the current internal state and the encoding of the current control input forward in time to produce the encoding of the next internal state in the latent space as shown in FIG. 8B.

The autoencoder also includes a first decoder subnetwork 808 configured to decode the encoding of the next internal state from the latent space to produce the unconstrained next internal state, processed by the neural operator 809 to produce the constrained next internal state 810 and a second decoder subnetwork 812 configured to decode the encoding of the current internal state to produce the current output 810 corresponding to the current internal state and the current internal input.

All operators 804, 806, 808, 809, 811, and 812 are neural operators, i.e., they represent neural networks parameterized by weights and biases of different neural layers. Training the NSSM 801, i.e., learning the parameters of neural operators, involves the minimization of a suitably defined cost function over the training dataset collected from the high-fidelity black-box model. Accordingly, in an embodiment of the invention, the loss function for learning the parameters of the NSSM is comprised of three loss terms, as defined below:

$$L = {L}_{r econ} + {L}_{pred , x} + {L}_{pred , y} .$$

The first term L_{recon} penalizes the reconstruction loss of the state vector associated with the auto-encoder pair (εₓ, [symbol] o [symbol] ₓ) i.e., the error between xₖ and [symbol] o [symbol] ₓ o εₓ(xₖ). The second term L_{pred,x} penalizes one-step prediction error loss in the state vector, i.e., the error between xₖ₊₁ and [symbol] o [symbol] ₓ( [symbol] o εₓ(xₖ)+εᵤ(uₖ)). The last term L_{pred,y} penalizes the prediction error loss in outputs, i.e., the error between yₖ and [symbol] [symbol] oεₓ(xₖ).

In particular, the loss terms for NSSM illustrated in FIG. 8A are given as follows

$${L}_{recon} = {MSE}_{0 : N} ( {x}_{k} , ∘ {𝒟}_{𝓍} ∘ {ℰ}_{𝓍} ( {x}_{k} ) )$$

$${L}_{pred , x} = {MSE}_{0 : N - 1} ( {x}_{k + 1} , ∘ {𝒟}_{𝓍} ( 𝒜 ∘ {ℰ}_{𝓍} ( {x}_{k} ) + {ℰ}_{𝓊} ( {u}_{k} ) ) )$$

$${L}_{pred , y} = {MSE}_{0 : N} ( {y}_{k} , ∘ {ℰ}_{𝓍} ( {x}_{k} ) )$$

where mean squared error (MSE) between two vectors vₖ and [symbol] ∈Rⁿ for k=0, 1, . . . . N is defined as follows

$${MSE}_{0 : N} = \frac{1}{n ( N + 1 )} {\sum }_{k = 0}^{N} {‖ {v}_{k} - ‖}^{2}$$

Since all loss terms are differentiable, the parameters of NSSM are optimized to minimize the total loss using standard machine learning algorithms such as stochastic gradient descent or its variants.

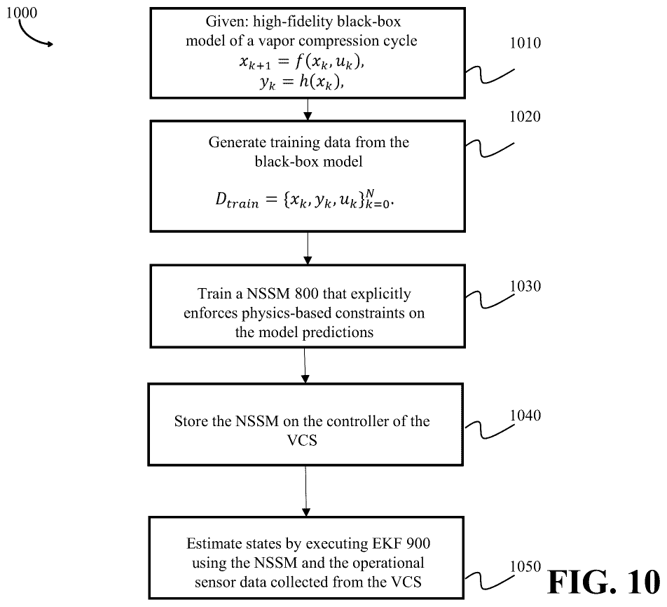

FIG. 10 shows a flowchart 1000 for the training and execution stages of estimating the internal states of a digital twin using the Kalman filter of FIGS. 9A and 9B according to an embodiment configured to perform a task for an operation of VCS. Given the high-fidelity black-box model 1010 of a VCS, the embodiment generates 1020 training data. Examples of the high-fidelity black-box model include digital twins using PDE calculations.

The training data is used to train 1030 a NSSM 800 that explicitly enforces physics-based constraints on the model predictions. The NSSM is stored 1040 on the controller that controls the VCS and the internal states of the digital twin and/or the internal states of VCS are tracked 1050 by executing EKF 900 using the NSSM and the operational sensor data collected from the VCS.

### Exemplary Implementations

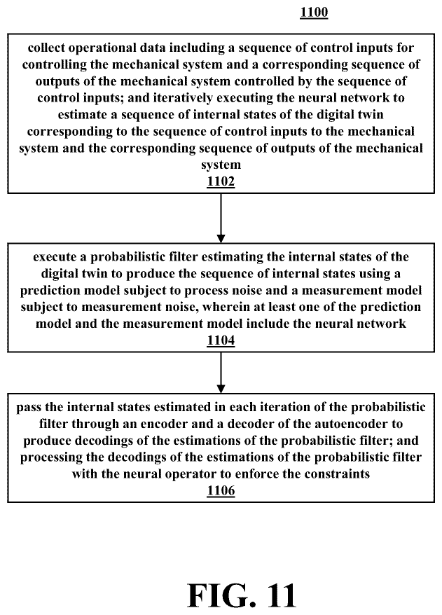

FIG. 11 is a flowchart of an example process 1100 according to some embodiments. In some implementations, one or more process blocks of FIG. 11 may be performed by a device including a processor. Process 1100 may include additional implementations, such as any single implementation or any combination of implementations described below and/or in connection with one or more other processes described elsewhere herein.

A first implementation, process 1100 further includes collecting operational data including a sequence of control inputs for controlling the mechanical system and a corresponding sequence of outputs of the mechanical system controlled by the sequence of control inputs; and iteratively executing the neural network to estimate a sequence of internal states of the digital twin corresponding to the sequence of control inputs to the mechanical system and the corresponding sequence of outputs of the mechanical system.

A second implementation, alone or in combination with the first implementation, process 1100 further includes executing a probabilistic filter estimating the internal states of the digital twin to produce the sequence of internal states using a prediction model subject to process noise and a measurement model subject to measurement noise, where at least one of the prediction model and the measurement model includes the neural network.

A third implementation, alone or in combination with the first and second implementation, process 1100 further includes passing the internal states estimated in each iteration of the probabilistic filter through an encoder and a decoder of the autoencoder to produce decodings of the estimations of the probabilistic filter; and processing the decodings of the estimations of the probabilistic filter with the neural operator to enforce the constraints.

Although FIG. 11 shows example blocks of process 1100, in some implementations, process 1100 may include additional blocks, fewer blocks, different blocks, or differently arranged blocks than those depicted in FIG. 11. Additionally, or alternatively, two or more of the blocks of process 1100 may be performed in parallel.

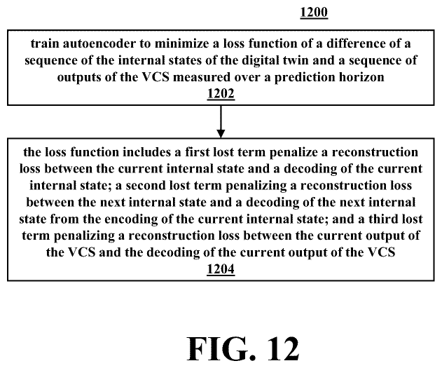

FIG. 12 is a schematic of an example process 1200 for training the neural network according to some embodiments. Process 1200 may include additional implementations, such as any single implementation or any combination of implementations described below and/or in connection with one or more other processes described elsewhere herein.

In a first implementation, the autoencoder is trained to minimize a loss function of a difference of a sequence of the internal states of the digital twin and a sequence of outputs of the VCS measured over a prediction horizon. In a second implementation, alone or in combination with the first implementation, the loss function includes a first lost term penalizing a reconstruction loss between the current internal state and a decoding of the current internal state; a second lost term penalizing a reconstruction loss between the next internal state and a decoding of the next internal state from the encoding of the current internal state; and a third lost term penalizing a reconstruction loss between the current output of the VCS and the decoding of the current output of the VCS.

Although FIG. 12 shows example blocks of process 1200, in some implementations, process 1200 may include additional blocks, fewer blocks, different blocks, or differently arranged blocks than those depicted in FIG. 12. Additionally, or alternatively, two or more of the blocks of process 1200 may be performed in parallel.

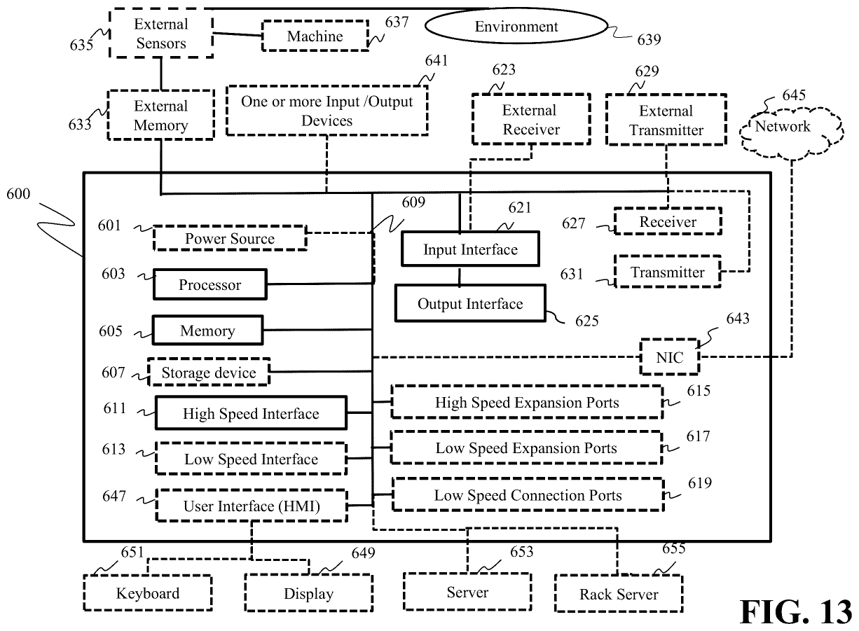

FIG. 13 shows a schematic diagram of a computing device 1300 that can be used for implementing the device 101 of the present disclosure. The computing device 1300 includes a power source 1301, a processor 1303, a memory 1305, a storage device 1307, all connected to a bus 1309. Further, a high-speed interface 1311, a low-speed interface 1313, high-speed expansion ports 1315 and low speed connection ports 1317, can be connected to the bus 1309. In addition, a low-speed expansion port 1319 is in connection with the bus 1309. Further, an input interface 1321 can be connected via the bus 1309 to an external receiver 1323 and an output interface 1325. A receiver 1327 can be connected to an external transmitter 1329 and a transmitter 1331 via the bus 1309. Also connected to the bus 1309 can be an external memory 1333, external sensors 1335, machine(s) 1337, and an environment 1339. Further, one or more external input/output devices 1341 can be connected to the bus 1309. A network interface controller (NIC) 1343 can be adapted to connect through the bus 1309 to a network 1345, wherein data or other data, among other things, can be rendered on a third-party display device, third party imaging device, and/or third-party printing device outside of the computer device 1300.

The memory 1305 can store instructions that are executable by the computer device 1300 and any data that can be utilized by the methods and systems of the present disclosure. The memory 1305 can include random access memory (RAM), read only memory (ROM), flash memory, or any other suitable memory systems. The memory 1305 can be a volatile memory unit or units, and/or a non-volatile memory unit or units. The memory 1305 may also be another form of computer-readable medium, such as a magnetic or optical disk.

The storage device 1307 can be adapted to store supplementary data and/or software modules used by the computer device 1300. The storage device 1307 can include a hard drive, an optical drive, a thumb-drive, an array of drives, or any combinations thereof. Further, the storage device 1307 can contain a computer-readable medium, such as a floppy disk device, a hard disk device, an optical disk device, or a tape device, a flash memory or other similar solid-state memory device, or an array of devices, including devices in a storage area network or other configurations. Instructions can be stored in an information carrier. The instructions, when executed by one or more processing devices (for example, the processor 1303), perform one or more methods, such as those described above.

The computing device 1300 can be linked through the bus 1309, optionally, to a display interface or user Interface (HMI) 1347 adapted to connect the computing device 1300 to a display device 1349 and a keyboard 1351, wherein the display device 1349 can include a computer monitor, camera, television, projector, or mobile device, among others. In some implementations, the computer device 1300 may include a printer interface to connect to a printing device, wherein the printing device can include a liquid inkjet printer, solid ink printer, large-scale commercial printer, thermal printer, UV printer, or dye-sublimation printer, among others.

The high-speed interface 1311 manages bandwidth-intensive operations for the computing device 1300, while the low-speed interface 1313 manages lower bandwidth-intensive operations. Such allocation of functions is an example only. In some implementations, the high-speed interface 1311 can be coupled to the memory 1305, the user interface (HMI) 1347, and to the keyboard 1351 and the display 1349 (e.g., through a graphics processor or accelerator), and to the high-speed expansion ports 136, which may accept various expansion cards via the bus 1309.

In an implementation, the low-speed interface 1313 is coupled to the storage device 1307 and the low-speed expansion ports 1317, via the bus 1309. The low-speed expansion ports 1317, which may include various communication ports (e.g., USB, Bluetooth, Ethernet, wireless Ethernet) may be coupled to the one or more input/output devices 1341. The computing device 1300 may be connected to a server 1353 and a rack server 1355. The computing device 1300 may be implemented in several different forms. For example, the computing device 1300 may be implemented as part of the rack server 1355.

The present disclosure provides the device 101 for controlling the system 103 based on the internal states of the digital twin 105 of the system 103. As the digital twin 105 generates the same outputs as the system 103 through the change of their internal states, the internal states of the digital twin 105 can be used to determine the control input that leads to the desired output. Further, because the internal state is an accurate representation of the operation of the system 103 than the measurements, the feedback control of the system 103 based on the internal states of the digital twin 105 is accurate than the feedback control based on the measurements of the system 103.

The description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like reference numbers and designations in the various drawings indicated like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed, but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine-readable medium. A processor(s) may perform the necessary tasks.

Various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine. Typically, the functionality of the program modules may be combined or distributed as desired in various embodiments.

Embodiments of the present disclosure may be embodied as a method, of which an example has been provided. The acts performed as part of the method may be ordered in any suitable way. Accordingly, embodiments may be constructed in which acts are performed in an order different than illustrated, which may include performing some acts concurrently, even though shown as sequential acts in illustrative embodiments.

Further, embodiments of the present disclosure and the functional operations described in this specification can be implemented in digital electronic circuitry, in tangibly-embodied computer software or firmware, in computer hardware, including the structures disclosed in this specification and their structural equivalents, or in combinations of one or more of them. Further some embodiments of the present disclosure can be implemented as one or more computer programs, i.e., one or more modules of computer program instructions encoded on a tangible non transitory program carrier for execution by, or to control the operation of, data processing apparatus. Further still, program instructions can be encoded on an artificially generated propagated signal, e.g., a machine-generated electrical, optical, or electromagnetic signal, which is generated to encode information for transmission to suitable receiver apparatus for execution by a data processing apparatus. The computer storage medium can be a machine-readable storage device, a machine-readable storage substrate, a random or serial access memory device, or a combination of one or more of them.

According to embodiments of the present disclosure the term “data processing apparatus” can encompass all kinds of apparatus, devices, and machines for processing data, including by way of example a programmable processor, a computer, or multiple processors or computers. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, or a combination of one or more of them.

A computer program (which may also be referred to or described as a program, software, a software application, a module, a software module, a script, or code) can be written in any form of programming language, including compiled or interpreted languages, or declarative or procedural languages, and it can be deployed in any form, including as a stand-alone program or as a module, component, subroutine, or other unit suitable for use in a computing environment. A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub programs, or portions of code.

A computer program can be deployed to be executed on one computer or on multiple computers that are located at one site or distributed across multiple sites and interconnected by a communication network. Computers suitable for the execution of a computer program include, by way of example, can be based on general or special purpose microprocessors or both, or any other kind of central processing unit. Generally, a central processing unit will receive instructions and data from a read only memory or a random access memory or both. The essential elements of a computer are a central processing unit for performing or executing instructions and one or more memory devices for storing instructions and data.

Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described in this specification can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

Although the present disclosure has been described with reference to certain preferred embodiments, it is to be understood that various other adaptations and modifications can be made within the spirit and scope of the present disclosure. Therefore, it is the aspect of the append claims to cover all such variations and modifications as come within the true spirit and scope of the present disclosure.

Claimed is:

1. A method for performing a task based on an internal state of a digital twin simulating an operation of a mechanical system, wherein at least some state variables of the internal states of the digital twin are subject to constraints derived from physics of a structure of the mechanical system, wherein the method uses a processor coupled with stored instructions implementing the method, wherein the instructions, when executed by the processor carry out steps of the method, comprising:
executing a neural network including (1) an autoencoder trained to process a current internal state of the digital twin and a current control input to the mechanical system to produce a current output of the mechanical system caused by the current control input and an unconstrained next internal state of the digital twin transitioned from the current internal state based on the current control input, and (2) a neural operator trained to modify the unconstrained next internal state of the digital twin to produce a constrained next internal state of the digital twin satisfying the constraints; and
performing the task based on the constrained next internal state of the digital twin.

2. The method of claim 1, wherein the constraints define a linear inequality in terms of the internal states, and wherein the neural operator encodes the constraints using an equivalent rays-based description of a polytope defined by the linear inequality, such that the unconstrained next internal state is passed through a fully connected neural layer which produces a nonnegative vector of a dimension compatible with a matrix of rays describing the polytope, and a product of the nonnegative vector with the matrix of rays results in the constrained next internal state satisfying the constraints.

3. The method of claim 1, wherein the mechanical system is a vapor compression system (VCS), and wherein the constraints mandate the internal states of the digital twin of the VCS to satisfy decreasing pressure in a direction of refrigerant flow in the VCS.

4. The method of claim 1, wherein the constraints define box constraints for one or a combination upper and lower bound on the internal states of the digital twin.

5. The method of claim 1, wherein the mechanical system is a vapor compression system (VCS), and wherein the task includes one or a combination of an estimation of heating/cooling capacities delivered by the VCS to a space, a computation of refrigerant mass in the VCS, control of the VCS, a performance monitoring of the operation of the VCS, anomaly detection in the operation of the VCS, a model predictive control of the VCS.

6. The method of claim 1, further comprising:
collecting operational data including a sequence of control inputs for controlling the mechanical system and a corresponding sequence of outputs of the mechanical system controlled by the sequence of control inputs; and
iteratively executing the neural network to estimate a sequence of internal states of the digital twin corresponding to the sequence of control inputs to the mechanical system and the corresponding sequence of outputs of the mechanical system.

7. The method of claim 6, further comprising:
executing a probabilistic filter estimating the internal states of the digital twin to produce the sequence of internal states using a prediction model subject to process noise and a measurement model subject to measurement noise, wherein at least one of the prediction model and the measurement model include the neural network.

8. The method of claim 7, further comprising:
passing the internal states estimated in each iteration of the probabilistic filter through an encoder and a decoder of the autoencoder to produce decodings of the estimations of the probabilistic filter; and
processing the decodings of the estimations of the probabilistic filter with the neural operator to enforce the constraints.

9. The method of claim 6, wherein the probabilistic filter is an extended Kalman filter with a model linearization obtained by differentiation of the neural network.

10. The method of claim 1, wherein the autoencoder architecture comprises:
a first encoder subnetwork configured to encode the current internal state into latent space to produce an encoding of the current internal state in the latent space;
a second encoder subnetwork configured to encode the current control input into the latent space to produce an encoding of the current control input in the latent space;
a latent subnetwork configured to propagate forward in time one or a combination of the encoding of the current internal state and the encoding of the current control input to produce an encoding of the next internal state in the latent space;
a first decoder subnetwork configured to decode the encoding of the next internal state from the latent space to produce the unconstrained next internal state;
a second decoder subnetwork configured to decode the encoding of the current internal state to produce the current output corresponding to the current internal state and the current internal input.

11. The method of claim 10, wherein the latent subnetwork is configured to propagate the encoding of the current internal state forward in time and combine the propagated encoding of the current internal state with the encoding of the current control input to produce the encoding of the next internal state in the latent space.

12. The method of claim 10, wherein the latent subnetwork is configured to propagate a mix of the encoding of the current internal state and the encoding of the current control input forward in time to produce the encoding of the next internal state in the latent space.

13. The method of claim 10, wherein the autoencoder is trained to minimize a loss function of a difference of a sequence of the internal states of the digital twin and a sequence of outputs of the VCS measured over a prediction horizon.

14. The method of claim 13, wherein the loss function includes
a first lost term penalizing a reconstruction loss between the current internal state and a decoding of the current internal state;
a second lost term penalizing a reconstruction loss between the next internal state and a decoding of the next internal state from the encoding of the current internal state; and
a third lost term penalizing a reconstruction loss between the current output of the VCS and the decoding of the current output of the VCS.

15. The method of claim 10, wherein the autoencoder is trained jointly with the neural operator.

16. The method of claim 1, further comprising:
controlling the mechanical system based on the constrained next internal states of the digital twin to perform the task.

17. A device for performing a task based on an internal state of a digital twin simulating an operation of a mechanical system comprising:
one or more processors configured to:
execute a neural network including (1) an autoencoder trained to process a current internal state of the digital twin and a current control input to the mechanical system to produce a current output of the mechanical system caused by the current control input and an unconstrained next internal state of the digital twin transitioned from the current internal state based on the current control input, and (2) a neural operator trained to modify the unconstrained next internal state of the digital twin to produce a constrained next internal state of the digital twin satisfying the constraints; and
perform the task based on the constrained next internal state of the digital twin.

18. The device of claim 17, wherein the constraints define a linear inequality in terms of the internal states, and the neural operator encodes the constraints using an equivalent rays-based description of a polytope defined by the linear inequality, such that the unconstrained next internal state is passed through a fully connected neural layer which produces a nonnegative vector of a dimension compatible with a matrix of rays describing the polytope, and a product of the nonnegative vector with the matrix of rays results in the constrained next internal state satisfying the constraints.

19. The device of claim 17, wherein the mechanical system is a vapor compression system (VCS), and the constraints mandate the internal states of the digital twin of the VCS to satisfy decreasing pressure in a direction of refrigerant flow in the VCS.

20. The device of claim 17, wherein the one or more processors are further configured to:
collect operational data including a sequence of control inputs for controlling the mechanical system and a corresponding sequence of outputs of the mechanical system controlled by the sequence of control inputs; and
iteratively execute the neural network to estimate a sequence of internal states of the digital twin corresponding to the sequence of control inputs to the mechanical system and the corresponding sequence of outputs of the mechanical system.
